(19) United States
(12) Patent Application Publication
(10) Pub. No.: US 2026/0174129 A1
(43) Pub. Date: Jun. 25, 2026

(54) COMPUTING DEVICE

(71) Applicant: NICOVENTURES TRADING LIMITED, London (GB)

(72) Inventor: Zhihuang XIAO, London (GB)

(21) Appl. No.: 19/124,494

(22) PCT Filed: Oct. 26, 2023
(86) PCT No.: PCT/GB2023/052798

§ 371 Date: Apr. 25, 2025

(30) Foreign Application Priority Data
Oct. 26, 2022 (GB) 2215844.8
Oct. 26, 2022 (GB) 2215852.1
Sep. 15, 2023 (GB) 2314116.1
Sep. 15, 2023 (GB) 2314119.5

(51) Int. Cl. A24F 40/40

(52) U.S. Cl. CPC A24F 40/40

(57) ABSTRACT

An application specific integrated circuit (ASIC) package for use in an electrical or electronic device is disclosed, the ASIC package comprising a plurality of functional units and a plurality of terminals. Each functional unit is configured with control logic operable to provide a discrete monitoring and/or control function associated with an aspect of operation of the electrical or electronic device. Each terminal comprises a plurality of input and/or output terminals, each input and/or output terminal being connected to at least one of the functional units. An operating status of each of the functional units is independently configurable into one of an enabled and non-enabled operational state, and the ASIC package is configured to be set into a target functional configuration selected from a plurality of different functional configurations. Each of the plurality of functional configurations comprises a different combination of operating states associated with respective ones of the plurality of functional units. In this way, the ASIC package provides a degree of customisability of supported functions, enabling the same ‘master’ ASIC package (e.g. the as-fabricated ASIC package) to be modified after manufacture to tailor the supported function set to a specific one of a plurality of devices.

### FIELD

The present disclosure relates to computing devices, and in particular, computing devices comprising application specific integrated circuits (ASICs).

### BACKGROUND

It is typical for electrical/electronic devices, for example consumer handheld electronic devices, to comprise a controller unit to support functionality/operability of the device. Such a controller provides control logic, implemented by hardware optionally in conjunction with firmware/software, to provide processing functionality. A controller unit will typically be formatted into a package comprising power terminals (e.g. V_{supply} and V_{ground}) connected to a power source (e.g. a battery) and a plurality of input and/or output terminals connected to electrical/electronic components of the device, and the processing comprises the receiving of input signals from components of the device, and the provision of output signals to components of the device. Such signals may be analogue and/or digital, depending on the device whose functionality is supported by the controller unit.

A controller for an electrical device, such as a handheld consumer electrical device, may in some instances comprise a microcontroller unit (MCU), which comprises a plurality of input and output terminals to enable the MCU to receive input signals and provide output signals to support functionality of the device. Such an MCU will typically be programmable to provide customised functionality, such that the control logic provided by the MCU can be adapted to support functionality of a specific device, having a particular set of control functions which are required to be supported (e.g. corresponding to the capabilities of the device/system electrical hardware/components). Where a set of required functions to be provided by a controller element is closed and thus well-defined, a controller unit may be provided as an application specific integrated circuit (ASIC). Unlike an MCU, in which the control logic is provided by machine code/software/firmware stored in system memory, which can be tailored to the specific functionality to be supported by the device in which the MCU is to be implemented, the control logic of an ASIC chip is typically entirely defined by the physical gate architecture of the circuitry comprised in the chip, with the latter being designed specifically to support a single, well-defined use case (which may comprise a plurality of functions). In general, ASICs may be considered to offer certain advantages over MCUs in certain use cases, including greater potential for optimisation/efficiency, and reduced unit cost, provided manufacturing volumes are high enough to offset the typically substantial design and tooling costs. As a result, ASICs typically tend to be highly optimised for their specific application(s), but lack flexibility to adapt their operation post-manufacture; whilst MCUs are less well optimised for any specific application, but offer significant flexibility to apply the same physical controller (with application-specific software/machine code) to different use cases. Thus use of either an ASIC or MCU as a controller (e.g. of an aerosol provision system) typically involves a trade-off between unit cost, functional flexibility, and efficiency/optimisation, and the corresponding manufacturing challenges.

The inventor has recognised that it may be advantageous to provide a controller unit for electrical devices (e.g. handheld consumer electrical devices) which combines some of the benefits which are typically respectively associated with either ASICs or MCUs in the same controller. Various approaches are described herein which seek to help address or mitigate at least some of the issues discussed above.

### SUMMARY

According to a first aspect of the present disclosure, there is provided an application specific integrated circuit, ASIC, package, for use in an electrical or electronic device, the ASIC package comprising: a plurality of functional units, wherein each of the plurality of functional units is configured with control logic operable to provide a discrete monitoring and/or control function associated with an aspect of operation of the electrical or electronic device, and wherein an operating status of each of the functional units is independently configurable into one of an enabled and non-enabled operational state; and a plurality of terminals, comprising a plurality of input and/or output terminals, wherein each one of the plurality of input and/or output terminals is connected to at least one of the plurality of functional units; wherein the ASIC package is configured to be set into a target functional configuration selected from a plurality of different functional configurations, wherein each of the plurality of functional configurations comprises a different combination of operating states associated with respective ones of the plurality of functional units.

According to a second aspect of the present disclosure, there is provided a method of modifying an application specific integrated circuit, ASIC, package, for use in an electrical or electronic device, the ASIC package comprising: a plurality of functional units, wherein each of the plurality of functional units is configured with control logic operable to provide a discrete monitoring and/or control function associated with an aspect of operation of the electrical or electronic device, and wherein an operating status of each of the functional units is independently configurable into one of an enabled and non-enabled operational state; and a plurality of terminals, comprising a plurality of input and/or output terminals, wherein each one of the plurality of input and/or output terminals is connected to at least one of the plurality of functional units; wherein the method comprises setting the ASIC package into a target functional configuration selected from a plurality of different functional configurations, wherein each of the plurality of functional configurations comprises a different combination of operating states associated with respective ones of the plurality of functional units.

According to a third aspect of the present disclosure, there is provided a data processing apparatus comprising means for carrying out the method according to the second aspect.

According to a fourth aspect of the present disclosure, there is provided a computer program product comprising instructions which, when the program is executed by a computer, cause the computer to carry out the method of the second aspect.

According to a fifth aspect of the present disclosure, there is provided a computer-readable medium having stored thereon the computer program product according to the fourth aspect.

It will be appreciated that features and aspects of the invention described above in relation to the first and other aspects of the invention are equally applicable to, and may be combined with, embodiments of the invention according to other aspects of the invention as appropriate, and not just in the specific combinations described above.

### BRIEF DESCRIPTION OF THE DRAWINGS

Embodiments of the disclosure will now be described, by way of example only, with reference to the accompanying drawings, in which:

Embodiments of the disclosure will now be described, by way of example only, with reference to the accompanying drawings, in which:

FIG. 1 is a schematic diagram of an aerosol provision system in which an ASIC package according to embodiments of the present disclosure may be implemented.

FIG. 2 is a schematic diagram of an ASIC package according to embodiments of the present disclosure.

FIG. 3 is a flowchart detailing aspects of operation of a power supply unit according to embodiments of the present disclosure.

FIG. 4 is a diagram detailing an exemplary relationship between charging rate and battery voltage according to embodiments of the present disclosure.

FIG. 5 is a schematic diagram of a power supply unit comprising a single switch.

FIG. 6 is a schematic diagram of a power supply unit according to embodiments of the present disclosure.

FIG. 7 is a flowchart detailing aspects of operation of a power supply unit according to embodiments of the present disclosure.

FIG. 8 is a schematic diagram of an ASIC package according to embodiments of the present disclosure.

### DETAILED DESCRIPTION

Aspects and features of certain examples and embodiments are discussed/described herein. Some aspects and features of certain examples and embodiments may be implemented conventionally and these are not discussed/described in detail in the interests of brevity. It will thus be appreciated that aspects and features of apparatus and methods discussed herein which are not described in detail may be implemented in accordance with any conventional techniques for implementing such aspects and features.

The present disclosure relates to application-specific integrated circuits (ASICs) and ASIC packages for electrical/electronic devices. Herein, aerosol provision systems/devices are presented as an exemplary use case in which embodiments of the present disclosure may be for the sake of providing a concrete example of a potential application for ASICs and operating schemes according to the present disclosure. However it will be understood that this operating context is merely exemplary, and the subject matter of the present disclosure may be applied in respect of other use cases for electrical/electronic devices in which the advantages of

ASICs according to the present disclosure are desirable. Thus whilst embodiments of an ASIC/ASIC package as described herein may in some instances be referred to as an ASIC/ASIC package configured for use in an electronic aerosol provision system, device, or consumable, ASICs/ASIC packages designed according to the same principles described herein may be applied in the context of any other kind of electronic/electrical/electro-mechanical devices or systems, and a controller unit comprising an ASIC package described herein may be referred to as a controller unit configured for use in an electrical/electronic system or device, or configured for use in a consumer electrical device/handheld consumer electronic device.

Aerosol provision systems are an example of a type of handheld consumer electrical device in which an ASIC package according to the present disclosure may be implemented, and which an ASIC package according to the present disclosure may be designed to support. Aerosol provision systems, which may comprise so-called ‘e-cigarettes’ or ‘electronic cigarettes’, or may comprise so-called ‘heat-not-burn’ or ‘tobacco heating’ devices, often, though not always, comprise a modular assembly including both a reusable part, which may be referred to herein as an aerosol provision device or control unit, and a replaceable (disposable) part which may be referred to herein as a consumable, article, cartridge, cartomiser, or pod unit. Often the replaceable part will comprise a supply aerosol generating material and an aerosol generator, and the reusable part will comprise a power supply (e.g. rechargeable power source) and a controller unit configured to provide control logic to support functions of the aerosol provision system. It will be appreciated these different parts may comprise further elements depending on the required functionality, as described further herein. Replaceable parts may be electrically and mechanically coupled to a reusable part for use, for example using a screw thread, bayonet, or magnetic coupling with appropriately arranged electrical contacts (in instances where an aerosol generator and/or other electrical components are comprised in the replaceable part). When the aerosol generating material in a replaceable part is exhausted, or the user wishes to switch to a different replaceable part having a different aerosol generating material, a replaceable part may be removed from the reusable part and a different/new replaceable part attached in its place. Devices conforming to this type of two-part modular configuration may generally be referred to as two-part devices. Alternatively, the components described above as distributed between a separable reusable part and a replaceable part may be integrated into a single housing, such that a part of the device containing aerosol generating material (e.g. a reservoir) is not designed to be replaced by a user. Such a device, which may be referred to as a single-part or uni-part aerosol provision system, may be configured to allow a user to refill a reservoir or container of aerosol generating material, or may not be designed to allow refill by a user. Such a device may be referred to as a ‘disposable’ aerosol provision system, and may be manufactured to comprise a battery and a supply of aerosol generating material which are sized to allow a certain number of puffs before the device is no longer able to generate aerosol for a user (e.g. because the supply of electrical power and/or aerosol generating material are exhausted). When this point is reached, the device may be configured to be disposed of or recycled. Disposable aerosol provision systems, which are designed for the entire aerosol provision system to be disposed of after a target number or range of puffs, may typically be designed to be relatively simple, with low per-unit production costs compared to reusable aerosol provision systems, and thus the inventor has recognised that the use of an ASIC package to provide control logic may be particularly advantageous in this context due to the typically higher degree of optimisation and lower unit cost, compared to typical MCU controller units, provided production volumes are sufficiently high to offset design and tooling costs.

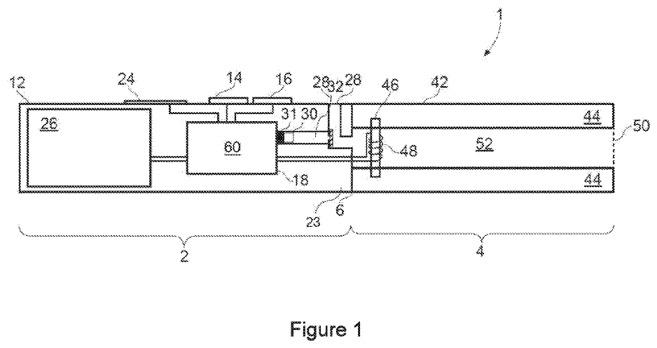

FIG. 1 is a cross-sectional view through an example aerosol provision system 1 in accordance with certain embodiments of the disclosure. The aerosol provision system 1 shown in FIG. 1 comprises two main components, namely an aerosol provision device or reusable part 2 and a replaceable/disposable cartridge or consumable part 4 (the terms ‘cartridge’, ‘consumable’, and ‘replaceable part’ may herein be used interchangeably). In normal use the reusable part 2 and the cartridge part 4 are releasably coupled together at an interface 6. When the cartridge part is exhausted or the user simply wishes to switch to a different cartridge part, the cartridge part may be removed from the reusable part and a replacement cartridge part attached to the reusable part in its place. The interface 6 provides a structural, electrical and airflow path connection between the two parts and may be established in accordance with conventional techniques, for example based around a screw thread, magnetic or bayonet fixing with appropriately arranged electrical contacts and openings for establishing the electrical connection and airflow path between the two parts as appropriate. The specific manner by which the replaceable part 4 mechanically mounts to the reusable part 2 is not significant to the principles described herein. As known to the skilled person, in some examples, an aerosol generator may be provided in the reusable part 2 rather than in the replaceable part 4, or the transfer of electrical power from the reusable part 2 to the replaceable part 4 may be wireless (e.g. based on electromagnetic induction), so that an electrical connection between the reusable part and the replaceable part is not needed.

The cartridge/consumable/replaceable part 4 may in accordance with certain embodiments of the disclosure be broadly conventional. In FIG. 1, the cartridge part 4 comprises a cartridge housing 42 formed of a plastics material. The cartridge housing 42 supports other components of the cartridge part and provides the mechanical interface 6 with the reusable part 2. The cartridge housing is generally circularly symmetric about a longitudinal axis along which the cartridge part couples to the reusable part 2. Within the cartridge housing 42 is a reservoir 44 that contains aerosol generating material. Aerosol generating material is a material that is capable of generating aerosol, for example when heated, irradiated or energized in any other way. Aerosol generating material may, for example, be in the form of a solid, liquid or gel which may or may not contain an active substance and/or flavourants. In some embodiments, the aerosol-generating material may comprise plant material such as tobacco. In some embodiments, the aerosol-generating material may comprise an “amorphous solid”, which may alternatively be referred to as a “monolithic solid” (i.e. non-fibrous). In some embodiments, the amorphous solid may be a dried gel. The amorphous solid is a solid material that may retain some fluid, such as liquid, within it. In some embodiments, the aerosol generating material may for example comprise from about 50 wt %, 60 wt % or 70 wt % of amorphous solid, to about 90 wt %, 95 wt % or 100 wt % of amorphous solid. The aerosol generating material may comprise one or more active substances and/or flavours, one or more aerosol-former materials, and optionally one or more other functional material.

An aerosol-former material may comprise one or more constituents capable of forming an aerosol, as known to the skilled person.

One or more active constituents/substances comprised in the consumable part may comprise one or more physiologically and/or olfactory active constituents which are included in the aerosolisable material in order to achieve a physiological and/or olfactory response in the user. In some embodiments, the active constituent is a physiologically active constituent and may be selected from nicotine, nicotine salts (e.g. nicotine ditartrate/nicotine bitartrate), nicotine-free tobacco substitutes, other alkaloids such as caffeine, cannabinoids, or mixtures thereof.

In the example shown schematically in FIG. 1, a reservoir 44 is provided configured to store a supply of liquid aerosol generating material. In this example, the liquid reservoir 44 has an annular shape with an outer wall defined by the cartridge housing 42 and an inner wall that defines an airflow path 52 through the cartridge part 4. The reservoir 44 is closed at each end with end walls to contain the aerosol generating material. The reservoir 44 may be formed in accordance with conventional techniques, for example it may comprise a plastics material and be integrally moulded with the cartridge housing 42. This configuration is exemplary, and any airflow configuration known to the skilled person may alternatively be used.

The cartridge (which may also be referred to herein as a consumable part) further comprises an aerosol generator 48 located towards an end of the reservoir 44 opposite to the mouthpiece outlet 50. An aerosol generator is an apparatus configured to cause aerosol to be generated from the aerosol-generating material. In some embodiments, the aerosol generator is a heater configured to subject the aerosol-generating material to heat energy, so as to release one or more volatile materials from the aerosol-generating material to form an aerosol. In some embodiments, the aerosol generator is configured to cause an aerosol to be generated from the aerosol-generating material without heating. For example, the aerosol generator may be configured to subject the aerosol-generating material to one or more of vibration, increased pressure, or electrostatic energy.

It will be appreciated that in a two-part device such as shown in FIG. 1, the aerosol generator may be in either of the reusable part 2 or the cartridge part 4. For example, in some embodiments, the aerosol generator 48 (e.g. a heater) may be comprised in the reusable part 2, and is brought into proximity with a portion of aerosol generating material in the cartridge 4 when the cartridge is engaged with the reusable part 2. In such embodiments, the cartridge may comprise a portion of aerosol generating material, and an aerosol generator 48 comprising a heater is at least partially inserted into or at least partially surrounds the portion of aerosol generating material as the cartridge 4 is engaged with the reusable part 2. In the example of FIG. 1, a wick 46 in contact with a heater 48 extends transversely across the cartridge airflow path 52 with its ends extending into the reservoir 44 of a liquid aerosol generating material through openings in the inner wall of the reservoir 44. The openings in the inner wall of the reservoir are sized to broadly match the dimensions of the wick 46 to provide a reasonable seal against leakage from the liquid reservoir into the cartridge airflow path without unduly compressing the wick, which may be detrimental to its fluid transfer performance.

In the example of FIG. 1, the wick 46 and heater 48 are arranged in the cartridge airflow path 52 such that a region of the cartridge airflow path 52 around the wick 46 and heater 48 in effect defines a vaporisation region for the cartridge part 4. Aerosol generating material in the reservoir 44 infiltrates the wick 46 through the ends of the wick extending into the reservoir 44 and is drawn along the wick by surface tension/capillary action (i.e. wicking). The heater 48 in this example comprises an electrically resistive wire coiled around the wick 46. In the example of FIG. 1, the heater 48 comprises a nickel chrome alloy (Cr20Ni80) wire and the wick 46 comprises a cotton bundle, but it will be appreciated the specific aerosol generator configuration is not significant to the principles described herein. In use electrical power may be supplied from the power source/battery 26 to the heater 48 by a controller 60, to vaporise an amount of aerosol generating material (aerosol generating material) drawn to the vicinity of the heater 48 by the wick 46. Vaporised aerosol generating material may then become entrained in air drawn along the cartridge airflow path from the vaporisation region towards the mouthpiece outlet 50 for user inhalation. Although the aerosol generator 48 illustrated in FIG. 1 comprises a resistive wire coiled around a wick 46, this is not essential and it will be appreciate that other forms of aerosol generator may be used, such as a ceramic heater, flat plate heater, an inductive drive unit (e.g. a drive coil) providing a magnetic field to cause heating of a susceptor element in contact with aerosol generating material, etc.

The outer housings 12/42 of may be formed, for example, from a plastics or metallic material and in this example the housing 12 of the reusable part has a cross section generally conforming to the shape and size of the cartridge part 4 so as to provide a smooth transition between the two parts at the interface 6. In the example of FIG. 1, the air inlet 28 connects to an airflow path 51 through the reusable part 2. The reusable part airflow path 51 in turn connects to the cartridge airflow path 52 across the interface 6 when the reusable part 2 and cartridge part 4 are connected together. Thus, when a user inhales on the mouthpiece opening 50, air is drawn in through the air inlet 28, along the reusable part airflow path 51, across the interface 6, through the aerosol generation region in the vicinity of the aerosol generator 48 (where vaporised aerosol generating material becomes entrained in the air flow), along the cartridge airflow path 52, and out through the mouthpiece opening 50 for user inhalation.

The power source 26 in this example is a rechargeable battery and may be of a conventional type, for example of the kind normally used in electronic cigarettes and other applications requiring provision of relatively high currents over relatively short periods. The power source 26 may be recharged through a charging connector in the reusable part housing 12, for example a USB connector. In other instances, for example in disposable aerosol provision system, the power source 26 may not be configured to be rechargeable by a user, and a charging connector may not be provided. The power source 26 may be supplied fully charged, and is configured to be disposed of with all or part of the aerosol provision system 1 when it has been fully discharged (i.e. when it no longer provides sufficient power to enable generation of aerosol).

One or more user input mechanisms (e.g. buttons 14, 16) may be provided, which in this example are conventional mechanical buttons, for example comprising a spring mounted component which may be pressed by a user to establish an electrical contact. In this regard, the input buttons may be considered input devices for detecting user input and the specific manner in which the buttons are implemented is not significant. The buttons may be assigned to functions such as switching the aerosol provision system 1 on and off, and adjusting user settings such as a power to be supplied from the power source 26 to an aerosol generator 48. However, the inclusion of user input buttons is optional, and in some embodiments buttons may not be included.

A visual feedback mechanism/display unit 24 may be provided to give a user with a visual indication of various characteristics associated with the aerosol provision system, for example current power setting information, remaining power source power, and so forth. The display may be implemented in various ways. In this example the display 24 may comprise a conventional pixilated LCD screen that may be driven by the controller 60 to display the desired information in accordance with conventional techniques. In other implementations the display may comprise one or more discrete indicators, for example LEDs (not shown), that are arranged to display the desired information, for example through particular colours and/or illumination patterns. In some examples, the display unit 24 may comprise a touchscreen display providing functionality which may alternatively or additionally be provided by one or more buttons as described further herein. More generally, the manner in which a display is provided and information is displayed to a user using such a display is not significant to the principles described herein. For example some embodiments may not include a visual display and may optionally include other means for providing a user with information relating to operating characteristics of the aerosol provision system, for example using audio or haptic feedback, or may not include any means for providing a user with information relating to operating characteristics of the aerosol provision system.

A controller unit 60 is suitably configured/programmed to control the operation of the aerosol provision system to support one or more functions, which may typically be defined in accordance with established functionality for such devices. The controller unit/processor circuitry 60 may be considered to logically comprise various sub-units/circuitry elements associated with different aspects of the operation of the aerosol provision system 1. Each of the sub-units described herein may be implemented in hardware (e.g. as a functional unit of In this example the controller 60 may comprise power supply control circuitry for controlling the supply of power from the power source 26 to the aerosol generator 48 in response to user input, user programming circuitry 20 for establishing configuration settings (e.g. user-defined power settings) in response to user input, as well as other functional units/circuitry associated functionality in accordance with the principles described herein and conventional operating aspects of electronic cigarettes, such as display driving circuitry and user input detection circuitry. Embodiments of ASIC packages described herein may be configured to operate as a controller unit 60 for an aerosol provision system as shown schematically in FIG. 1.

Reusable part 2 comprises an activation element which directly or indirectly allows a user to provide input to the controller 60 to indicate a demand for aerosol. The activation element may comprise an airflow sensor 30 which is electrically connected to the control unit 60. In most embodiments, the airflow sensor 30 comprises a so-called “puff sensor”, as known to the skilled person, in that the airflow sensor 30 is used to detect when a user is puffing on the device by detecting airflow in accordance with known approaches (e.g. a change in pressure, airflow speed, or acoustic signals associated with a puff). In the example shown in FIG. 1, the airflow sensor 30 is mounted to a printed circuit board 31 as described further herein, but this is not essential. The airflow sensor 30 may comprise any sensor which is configured to determine a characteristic of airflow in an airflow path 51 disposed between air inlet 28 and mouthpiece opening 50, for example a pressure sensor or transducer (for example a membrane or solid-state pressure sensor), a combined temperature and pressure sensor, or a microphone (for example an electret-type microphone), which is sensitive to changes in air pressure, including acoustical signals. The airflow sensor may typically be situated within a sensor cavity/chamber 32, which, where present, comprises the interior space defined by one or more chamber walls 34 in which an airflow sensor 30 can be fully or partially situated. In some embodiments, the airflow sensor 30 is mounted to a printed circuit board (PCB) 31, which comprises one of the chamber walls 34 of a sensor housing comprising the sensor chamber/cavity 32. A deformable membrane is disposed across an opening communicating between the sensor cavity 32 containing the sensor 30, and a portion of the airflow path disposed between air inlet 28 and mouthpiece opening 50. The deformable membrane covers the opening, and is attached to one or more of the chamber walls according to approaches described further herein. It will be appreciated an airflow sensor 30, where present, may not be positioned in a dedicated sensor cavity 32, and may be situated anywhere in the airflow path, according to any suitable approach known to the skilled person.

Whilst the aerosol provision system of FIG. 1 has been shown as comprising a replaceable part 4 and a reusable part 2, it will be appreciated this is only exemplary, and in other instances, such an aerosol provision system may comprise a single-part device, which may be designed to be disposable after an initial supply of electrical power and/or aerosol generating material, supplied at manufacture, have been exhausted. Thus an aerosol provision system 1 as shown in FIG. 1 or otherwise described herein may not comprise a connection interface 6, but rather the components comprised in the device (e.g. as shown in the example device of FIG. 1) may be housed within a single housing.

An aerosol provision system May 1 comprise communication circuitry configured to enable a connection to be established with one or more further electronic devices (for example, a smartphone, personal computer, external server, storage/charging case, and/or a refill/charging dock) to enable data transfer between the aerosol provision system 1 and further electronic device(s). In some embodiments, the communication circuitry is integrated into controller unit 60, and in other embodiments it is implemented separately (comprising, for example, separate application-specific integrated circuit(s)/circuitry/chip(s)/chipset(s)). For example, the communication circuitry may comprise a separate module to the controller 60 which, while connected to controller 60, provides dedicated data transfer functionality for the aerosol provision system. In some embodiments, the communication circuitry is configured to support communication between the aerosol provision system 1 and one or more further electronic devices over a wireless interface. The communication circuitry may be configured to support wireless communications between the aerosol provision system 1 and other electronic devices such as a case, a dock, a computing device such as a smartphone or PC, a base station supporting cellular communications, a relay node providing an onward connection to a base station, a wearable device, or any other portable or fixed device which supports wireless communications.

Wireless communications between the aerosol provision system 1 and a further electronic device may be configured according to known data transfer protocols such as Bluetooth, ZigBee, WiFi, Wifi Direct, GSM, 2G, 3G, 4G, 5G, LTE, NFC, RFID. More generally, it will be appreciated that any wireless network protocol can in principle be used to support wireless communication between the aerosol provision system 1 and further electronic devices. In some embodiments, the communication circuitry is configured to support communication between the aerosol provision system 1 and one or more further electronic devices over a wired interface. This may be instead of or in addition to the configuration for wireless communications set out above. The communication circuitry may comprise any suitable interface for wired data connection, such as USB-C, micro-USB or Thunderbolt interfaces. More generally, it will be appreciated the communication circuitry may comprise any wired communication interface which enables the transfer of data, according to, for example, a packet data transfer protocol, and may comprise pin or contact pad arrangements configured to engage cooperating pins or contact pads on a dock, case, cable, or other external device which can be connected to the aerosol provision system 1.

As set out further herein, the description of an aerosol provision system 1 in accordance with FIG. 1 is only provided as an exemplary use context for an ASIC package according to embodiments of the present disclosure, in order to provide a concrete example of a context for which such an ASIC package may be designed and fabricated. It will be appreciated herein that nothing herein is intended to limit the utility of an ASIC package according to embodiments of the present disclosure to the specific context of aerosol provision systems, and that the principles described herein for design and fabrication of an ASIC package as described herein, whether or not configured to be set into one of a plurality of target functional configurations to support functionality of a specific device, may be applied in respect of a device and/or set of devices from any field of electrical devices in which a controller unit, and particularly a controller unit comprising a conventional ASIC package, may be used to provide control logic. Thus, as a non-exhaustive list, an ASIC package according to embodiments of the present disclosure may be used as a controller unit in a handheld consumer electronic device (e.g. a digital camera, digital video camera, GPS unit, telephone, watch, digital music player), a household appliance (e.g. a washing machine, dryer, fridge, freezer, dishwasher, smart speaker, microwave, toaster, coffee maker, or blender), in a vehicle (e.g. in a car, aircraft, spacecraft, satellite, drone/UAV, or train), or a computer peripheral and/or module in a computer system (e.g. a sound or graphics card, wireless telecommunications controller, or network switch).

An electrical/electronic device, such as those listed above, may be at least partly characterised by comprising a set of functions which are provided by different electrical or electronic components of the device, with the control of said components being carried out by control logic implemented in one or more controller units. As described further herein, each function of the electronic device may typically be defined in terms of one or more components which implement said function, and a set of input and/or output signals passed between terminals of the controller element(s) via appropriate wired or wireless connections, which enable the one or more components to carry out their intended operations. For example, in the example context of an aerosol provision system, the following is a non-exhaustive list of potential functions:
An aerosol generation function may typically be implemented by an aerosol generator (e.g. a heater) connected to the controller by suitable electrical connections. The control logic of the controller may be configured to provide a suitable level of electrical power to the aerosol generator. This may be a fixed power level, or the power level may be varied (e.g. via DC-to-DC conversion to modulate the voltage of a drive signal transmitted to the aerosol generator, or use of a pulse-width modulation scheme to modulate the power via varying of the duty cycle of the drive signal). The drive signal may be output from the control element via an output pin, and the aerosol generator may be grounded directly to a ground pin of the control element, or to a common ground rail to which the control element is also connected. The control logic of the controller will typically be configured to trigger provision of the drive signal in response to an activation signal received at an input pin, for example from an actuation element as described further herein. The control logic may compare an input signal level from a sensor (e.g. an airflow sensor), and trigger provision of the aerosol generator drive signal in dependence on the input signal level (e.g. if it exceeds a predefined threshold), and/or the power of the drive signal may be modulated in dependence on the amplitude of the input signal (which, where the sensor is an airflow sensor, will typically be proportional to airflow speed/flow rate)
A visual feedback function may typically be implemented by a display unit, such as a 2D pixilated display, or one or more LEDs, connected to the controller by suitable electrical connections. The display unit may comprise a touchscreen unit to allow a user to provide control inputs to the device. The control logic of the controller may be configured to provide a suitable digital or analogue drive signal to the display unit, via one or more output pins. The control logic may determine to provide different visual feedback drive signals to the display unit according to approaches known to the skilled person, to indicate, for example, that the device battery has been discharged to a predefined threshold level, that an aerosol generator has been activated, that a certain number of puffs has been taken, that a certain level of power has been set for the drive signals to the aerosol generator, that a certain number of puffs has been taken since a certain point in time, or that an error has occurred in one or more aspects of operation of the device. Where the display unit is a touchscreen unit, the control logic may be configured to receive signals from the touchscreen which are indicative of user inputs, and process these to trigger control functions associated with operation of the device.
A haptic feedback function may typically be implemented by a haptic motor connected to the controller by suitable electrical connections. The control logic of the controller may be configured to provide a suitable drive signal (e.g. a specific waveform) to the haptic motor to provide haptic feedback, in response to a predefined condition being met. For example, a haptic feedback drive signal may be provided to indicate one or more of the events recited in association with the provision of visual feedback above. Different waveforms may be used to drive the haptic motor for different events/statuses to be indicated.
An audible feedback function may typically be implemented by an audible feedback element (e.g. a speaker) connected to the controller by suitable electrical connections. The control logic of the controller may be configured to provide a suitable drive signal (e.g. a specific waveform) to the audible feedback element to provide audible feedback, in response to a predefined condition being met. For example, an audible feedback drive signal may be provided to indicate one or more of the events recited in association with the provision of visual or haptic feedback above. Different waveforms may be used to drive the audible feedback element for different events/statuses to be indicated.
A battery charging function may typically be implemented by charging hardware (e.g. a suitable wired or inductive charging interface) and battery connected to the controller by suitable electrical connections. The control logic of the controller may be configured to regulate the charging power according to approaches known to the skilled person, including the prevention of further charging once the battery reaches a certain level of charge. The battery charging function may also provide safety functions to prevent spikes of charging power at the battery, and the controller may receive input signals from one or more sensors located to provide environmental information to enable charging to be controlled on the basis of, for example, battery temperature and/or ambient temperature, in order to reduce the rate of charging and/or stop charging if the battery temperature and/or ambient temperature are above and/or below predefined safety thresholds, as defined by the battery manufacturer.
A wireless communication function may typically be implemented a wireless communications module, typically configured to operate in accordance with a wireless communications standard (e.g. Bluetooth, ZigBee, WiFi, Wifi Direct, GSM, 2G, 3G, 4G, 5G, LTE, NFC, or RFID). The wireless communications module may be connected to the control element via one or more input and output terminals, with data being transmitted to and/or from the control element to the wireless module via suitable electrical connections; or the wireless communications module may be integrated into the control element, with internal interconnects to allow transmission of signals between the integrated wireless communications module and other functional modules of the control element.
A wired communication function may typically be implemented a wired communications module, typically configured to operate in accordance with a wired communications standard (e.g. USB-C, micro-USB or Thunderbolt). The wired communications module may be connected to the control element via one or more input and output terminals, with data being transmitted to and/or from the control element to the wired communications module via suitable electrical connections; or the wired communications module may be integrated into the control element, with internal interconnects to allow transmission of signals between the integrated wired communications module and other functional modules of the control element.

It will be appreciated that in any given electronic or electrical device supported by a controller unit, the device may comprise any functions known to the skilled person which are typically controlled at least in part by control logic implemented in a control element such as a suitable programmed MCU, or an ASIC. The set of functions will typically be defined by the particular field in which the device comprising the controller unit is to be used. Embodiments of a controller unit comprising a customisable ASIC as described herein may be applied in contexts other than that of aerosol provision systems, with suitable adaptation of the functional units/modules used to support the function set (e.g. through design of different functional modules; and different packaging of the ASIC in terms of casing and format, input voltage and current rating, power density, and number of input and output terminals), according to approaches known to the skilled person.

Typically, in an electronic/electrical device such as an aerosol provision system, support of functions such as those described above is provided via a controller unit comprising either a microcontroller unit (MCU) or application-specific integrated circuit (ASIC). Where an MCU is used, a unit is typically selected with suitable input voltage and current rating, casing, and terminal number and format, to support the power requirements of the components supporting the different functions, and the number of discrete inputs and outputs required. Control logic is typically provided by firmware/software, which is typically written in a higher-level general-purpose programming language, then compiled to machine code, stored in memory associated with the MCU, and operable to run on the MCU. Where an ASIC is used as a controller unit, in which the control logic is partly or entirely provided by a non-modifiable layout of hardware logic gates, the design of the ASIC is typically partly or entirely customised, based on the set of functions it is required to support. Accordingly, the capability of a typical ASIC is determined by design, and cannot be modified to support other use cases with different function sets (e.g. different devices having different functionality), even if these function sets overlap with the function set for which the ASIC was designed.

The inventor has recognised that it may be advantageous to provide an ASIC package which provides a degree of customisability of supported functions, to enable the same ‘master’ ASIC package (e.g. the as-fabricated ASIC package) to be modified after manufacture to tailor the supported function set to a specific one of a plurality of devices which the ASIC package may be modified to support.

Thus, according to embodiments of the present disclosure, there is provided an application specific integrated circuit, ASIC, package, for use in an electronic aerosol provision system, the ASIC package comprising: a plurality of functional units (these may be interchangeably referred to herein as ‘functional blocks’ or ‘functional modules’), wherein each of the plurality of functional units is configured with control logic operable to provide a discrete monitoring and/or control function associated with an aspect of operation of the electronic aerosol provision system, and wherein an operating status of each of the functional units is independently configurable into one of an enabled and non-enabled operational state (otherwise referred to herein as an operating state); and a plurality of terminals, comprising a plurality of power supply terminals and a plurality of input and/or output terminals, wherein each one of the plurality of input and/or output terminals is connected to at least one of the plurality of functional units; wherein the ASIC package is configured to be set into a target functional configuration selected from a plurality of different functional configurations, wherein each of the plurality of functional configurations comprises a different combination of operating statuses associated with respective ones of the plurality of functional blocks. Herein, the terminology of functional blocks may be used interchangeably with the terminology of functional units and functional modules.

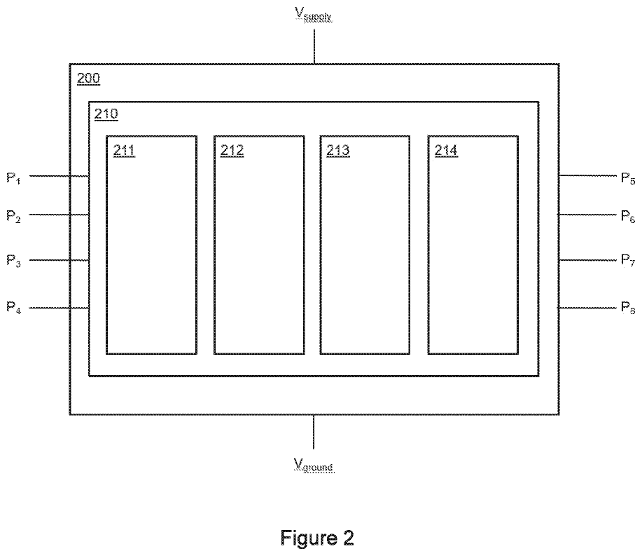

FIG. 2 shows an ASIC package 200 according to embodiments of the present disclosure. The ASIC package comprises hardware control logic 210, configured to support a plurality of functions associated with an electronic device (e.g. an aerosol provision system) in which the ASIC package 200 is implemented. The hardware control logic 210 is typically implemented on one or more semiconductor (e.g. silicon) dies/chips/wafers comprised in the ASIC package 200. The casing of the ASIC package 200 may be conventional, as may the structure of terminals (e.g. they may be pins or pads, designed for through-hole mounting, surface mounting, chip carrier mounting, pin grid array mounting, flat-package mounting, small-pin-count mounting, or any other mounting type known to the skilled person). In the example shown schematically in FIG. 2, four functional units/modules/blocks, 211, 212, 213, and 214, are shown comprised in the hardware control logic 210. The use of the terms ‘functional unit’ and/or ‘functional module’ are intended herein to indicate capabilities of the ASIC, and do not imply that the circuit elements (e.g. gates/cells) used to implement each functional unit/module of the ASIC are necessarily disposed on spatially distinct regions of the die/wafer/chip. Thus, whilst FIG. 2 shows functional units 211, 212, 213, and 214, as distinct regions/areas of the ASIC package, in some embodiments, circuitry associated with each of the functional units may be integrated with that of other functional units, such that a given region of the die may comprise circuit elements associated with more than one functional unit. With reference to the overview of an exemplary ASIC package design and fabrication approach set out below, the degree to which circuit elements (e.g. gates and interconnects) associated with different functional units are spatially associated/integrated may be determined during placement and routing stages, in which the layout of standard/custom cells and their electrical interconnects on the die material is defined. Whilst these stages may result in circuit elements of respective functional units being laid out on spatially distinct areas of the die (as shown schematically in FIG. 2), this may not be the case, particularly if the design process is carried out seeking to maximise the power density of the ASIC (within tolerable safety limits).

Typically, the signal processing pipeline of the ASIC package 200 (and/or each discrete functional unit) is fixed by the hardware (e.g. by the layout of cells and interconnects comprised in the ASIC package 200), such that the control logic can be highly optimised for the supported function(s) of a target device/use context, compared to the performance of a general-purpose MCU unit in the same device/use context. However, one or more functional units of the ASIC package may be programmable via modifiable software (e.g. firmware/microcode) to introduce flexibility into the control logic of the functional unit(s). This programmable capability may effected by providing software/microcode/a suitable CODEC to a specific functional unit, and/or one or more first programmable functional units may be configured to be provided with modifiable software code (e.g. firmware/micro-code/CODEC) to control the operation of one or more second functional units. For example, as one non-limiting example, a functional unit may be provided with a CODEC to support a voice command function. The CODEC comprised in a voice command functional unit is configured to sample data from a sensor (e.g. a flow sensor such as a microphone) and decode it into a digital signal which can be matched by the functional unit against a set of predefined digital signatures stored in a digital signature/voice command library on a memory element associated with the functional unit. Based on a match between a decoded digital signal and a specific predefined digital signature, the functional unit may be configured to trigger the operation of a different functional unit of the ASIC package 200 (e.g. changing a power level to be supplied to an electrical load by a power control functional unit). The voice command functional unit may associate digital signatures with control operations by receiving at least one audio signal, coding it via the stored CODEC into a digital signature which is stored in the command library, and receiving user inputs (e.g. from a manual input device comprised in the device in which the ASIC package is implemented, or via a wired or wireless connection with an external device supporting an APP for user input) which define what a control operation to be associated with the digital signature. The indicated control operation can then be associated with the signature in a data structure stored in the memory element.

The ASIC package 200 shown in FIG. 2 comprises a plurality of input and/or output terminals (indicated schematically as P1 to P8, and V_{supply}, and V_{ground}). These input and/or output terminals provide electrical interconnections between the control logic of the ASIC package, as defined by the functional units (e.g. 211, 212, 213, and 214, in the example of FIG. 2), and components of the electrical/electronic device external to the ASIC package 200). As described further herein, respective ones of a plurality of functions of the electrical/electronic device (‘device’) may supported by one or more functional units of the ASIC package 200, in conjunction with one or more components which are in electrical/electronic communication with the functional unit(s). For example, a given function of the device may be supported by one or components (e.g. a sensor element, wireless transceiver/antenna, manual input device, or. battery) which provide input signals (e.g. a supply of AC or DC power, a signal indicative of a sensed parameter, a signal encoding a data packet, a signal indicative of user input to a button or other manual input device) to one or more functional units of the ASIC package 200 (in a parallel or series signal path), wherein the transmission of digital or analogue electrical signals from the relevant component(s) to one or more of the functional units is effected via electrical connections between the component(s) and one or more terminals of the ASIC package 200, and electrical interconnects within the ASIC package (not shown in FIG. 2) linking each terminal to one or more functional units. Additionally, or alternatively, a given function of the device may be supported by one or more components (e.g. an aerosol generator or other electrical load, user feedback device, wireless transceiver, or power source) which receive(s) output signals (e.g. a charging current, a drive current for an aerosol generator or other electrical load, a signal encoding a data packet, or a signal encoding user feedback to be output by a user feedback device) from a functional unit of the ASIC package 200, wherein the transmission of digital or analogue electrical signals to the relevant component(s) from one or more functional units is effected via electrical connections between the component(s) and one or more terminals of the ASIC package 200, and the transmission of digital or analogue electrical signals from the relevant component(s) to one or more of the functional units is effected via electrical connections between the component(s) and one or more terminals of the ASIC package 200, and electrical interconnects within the ASIC package (not shown in FIG. 2) linking each terminal to one or more functional units. It will be appreciated the ASIC package 200 of FIG. 2 is represented schematically, and the interconnects via which circuit elements of each functional unit (e.g. 211, 212, 213, and 214) is electrically connected to one or more of the terminals of the ASIC package 200 are not explicitly shown as these will depend on the specific routing defined during design of an ASIC package for a particular set of potential use contexts. The specific network of interconnects from each functional unit of the ASIC package 200 to one or more terminals may be designed according to the particular function each functional unit is configured to support. It will be appreciated that each terminal may connect to more than one functional unit (for example, each functional unit is typically directly or indirectly connected to power terminals V_{supply} and V_{ground}), and that inputs/outputs associated with a given terminal may be associated simultaneously with a plurality of functional units (e.g. two or more functional units may receive the same input signal(s) provided at the same input pin(s), and/or two or more functional units may provide outputs at the same output pin(s), either simultaneously in time, or at different times). Furthermore, within the ASIC package 200, electrical interconnects between circuit elements associated with each respective functional unit may be provided to allow the passing of input and/or output signals in a signal flow/chain comprising multiple functional units, to support a certain required function. For example, a first functional unit may perform analogue-to-digital conversion (ADC) of input signals received at a first terminal, and pass resulting digital signals to a second functional unit; and/or a first functional unit may process one or more sensor inputs received at one or more input terminals, and send signals representative of sensed parameters to a second functional unit which packages the parameters into one or more data packets for storage in memory and/or transmission to an external computing device. Functional units may comprise circuit elements configured to implement control logic supporting any suitable function of an integrated circuit which is known to the skilled person. Examples of functional units in the operating context of an aerosol provision system may include, as a non-exhaustive list, analogue to digital conversion (ADC) units, digital to analogue conversion (DAC) units, flash memory units, binary register units, arithmetic logic units (ALU), power supply units for provision of current to an electrical load such as an aerosol generator/heater element (e.g. pulse width modulation (PWM) and/or pulse frequency modulation (PFM) drive units, such as switched mode power supply (SMPS) units), battery charging controller units, microelectromechanical system (MEMS) sensor units (e.g. MEMS airflow sensor units), single- or multiple-LED drive units, pixilated display panel drive units (e.g. touch-screen display panel drive units), over-current protection units, over-voltage protection units, ultra-low-voltage protection units, temperature management units, over-temperature protection units, short-circuit protection units, power-dissipation timing units, dual-switch units, power management integrated circuit units, power controller units (which may provide functionality corresponding to that of a switched mode power supply or boost conversion unit as described herein), protection circuit module units, inter-IC bus units, and ASIC package master control units (which modify the operation/control logic of other functional units of the ASIC package), the latter of which may comprise functional configuration setting units as referred to herein. It will be appreciated that the specific control logic implemented in each functional unit, and the manner in which said control logic is implemented (e.g. in terms of logic synthesis, placement, and routing), is not of particular significance, and may be implemented in accordance with standard procedures for integrated circuit/ASIC design known to the skilled person, and as described further herein. It will be further appreciated that whilst the ASIC package 200 may typically be configured such that all functional units comprise ASIC circuitry configured and fabricated according to ASIC design principles (e.g. comprising interconnected hardware gates fabricated via photolithography or a similar semiconductor fabrication process), the term ‘ASIC package’ can also refer to packages in which one or more functional units are implemented as a field-programmable gate array (FPGA), or MCU, provided at least one or more second functional unit(s) is/are implemented as an ASIC (i.e. the ASIC package may be considered in some instances to comprise a ‘system-on-chip’ (SOC) architecture, comprising at least one ASIC functional unit).

The ASIC package 200 may be fabricated according to approaches known to the skilled person. For example, the ASIC package 200 may be fabricated using a wafer/chip/die of semiconductor material comprising the control logic, implemented using standard and/or custom cells. For example, control logic of the selected set of functional units (as determined according to approaches set out further herein) may be translated into a hardware description language (e.g. Verilog or VHDL), in a register-transfer level (RTL) design stage. There may typically follow a functional verification stage, where the control logic is simulated (e.g. via bench testing, formal verification, emulation, or creating and evaluating an equivalent pure software model). There may typically follow a logic synthesis stage where the RTL design is transposed/compiled into a set of standard or custom cells, typically derived from a standard-cell library of logic gates configured to perform specific functions, to form a gate-level netlist. In a placement stage, the gate-level netlist is processed to derive a placement of the cells on a die (e.g. a semiconductor die comprising, for example, a silicon chip or wafer). During placement, the standard cell positioning is typically optimised for efficiency and robustness. In a routing stage, the netlist is typically used to design appropriate electrical connections between the cells, to provide the control logic. The output of the placement and routing stages is typically the derivation of the photo-mask(s) (‘masks’) which will be used to fabricate the circuitry of the ASIC on the die material using photolithographic techniques, though other techniques for fabrication of ASIC control logic may equally be used.

Where the operating context of the ASIC package 200 comprises an aerosol provision system, the aspects of operation in association with which the plurality of functional blocks of the ASIC package 200 are configured to provide monitoring and/or control functions may be selected from a list comprising:
control of current to an aerosol generator.
control of one or more display elements.
control of a haptic feedback element.
control of an audible feedback element.
monitoring of a user input interface.
control of a wireless communications module.
control of a wired communications module.
control of charging of a power supply comprised in the electronic aerosol provision system.
monitoring of a temperature associated with a operation of the aerosol provision system.
monitoring of a temperature associated with a charging or discharging operation (e.g. a temperature of a power source and/or power control circuitry).
monitoring of any interruption or error state associated with operation of the ASIC package and/or a device in which the ASIC package is integrated.
provision of safety functions in response to detection of abnormal electrical and/or temperature states associated with a host electrical/electronic device in which the ASIC package is used.
provision of inter-IC bus functionality for connection of external components to the ASIC package.

It will be appreciated this list is exemplary and non-exhaustive (and associated with a particular, non-limiting, exemplary use context), and a functional unit/block/module of the ASIC package may be configured to provide control logic associated with respective ones of all or a subset of any list of possible functions known to the skilled person, depending on the device(s) to be supported by a controller unit comprising the ASIC package. Accordingly, different ASIC packages according to the present disclosure may support different numbers of functional units/blocks/modules.

Thus, according to embodiments of the present disclosure, an ASIC package is fabricated implementing control logic associated with a set of n functional units, each of which supports different potential functionality of a device in which the ASIC package may be implemented (such as exemplary functions associated with an aerosol provision system, as described herein). It will be appreciated there may be a one-to-one mapping between functional units and the supported functions, and/or a plurality of functional units may support a single function (i.e. each of the plurality of units supports a sub-element of said function), and/or a plurality of functions may be supported by a single functional unit. Thus where the ASIC package 200 comprises n functional units, supporting m functions, there may be m=n functions, or m>n, functions, or m<n functions. What may be considered significant for the approaches herein is that the ASIC package 200 comprises at least two functional units, and that the ASIC package 200 may be configured to be set into a target functional configuration selected from a plurality of different functional configurations, wherein each of the plurality of functional configurations comprises a different combination of operating states/statuses associated with respective ones of the plurality of functional units. Thus each of the n functional units may be configured into a different operating status (e.g. enabled/disabled), either reversibly or non-reversibly, depending on what subset of the n functional units is required in a given context, based on the function set the context requires the ASIC package to support. The set of n functional units is typically defined for a given ASIC package to cover a total (or ‘global’) set of functions which may be required across a set of devices/use contexts in which the ASIC package may be used, each of which may have overlapping functional requirements. Table 1 shows 3 exemplary use contexts, Context A, Context B, and Context C, indicating which of 10 global functions (i.e. F1 to F10) are required to be supported in each context (‘1’ indicates function requires support, and ‘0’ indicates function does not require support). Whilst each context comprises fewer than 10 functions (i.e. it comprises a local, device specific function set), it can be seen that the total, global function set required to support any of the specific contexts comprises all of the functions F1 to F10. This principle can be generalised to determine a global function set for any number of contexts, each comprising a local function set.

TABLE 1

| | | Function | | | | | | | | | |
|---|---|---|---|---|---|---|---|---|---|---|---|
| | | F1 | F2 | F3 | F4 | F5 | F6 | F7 | F8 | F9 | F10 |
| Context | A | 0 | 1 | 1 | 1 | 1 | 0 | 1 | 0 | 0 | 0 |
| | B | 0 | 0 | 1 | 1 | 0 | 0 | 0 | 0 | 1 | 1 |
| | C | 1 | 1 | 0 | 0 | 1 | 0 | 0 | 0 | 1 | 0 |

This relationship between each of a plurality of specific contexts and the required operating status of each of the n functional units of the global function set is further illustrated in an aerosol provision system context by the following examples. An exemplary Device A is configured with components to support 3 functions, namely control of a heater, control of a display element comprising an LED, and monitoring of an operating parameter (e.g. heating temperature). More specifically, Device A may be a relatively simple (e.g. disposable) device, which is not configured to be recharged or refilled with aerosol generating material, and which has a simple, single-LED display element, and a temperature sensor to detect overheating of the heater. Exemplary Device B is be a more complex device, supporting a wider range of functions. It may implement the same heater control scheme and temperature sensing scheme as Device A, but comprise a more complex display element (e.g. an illuminated, pixilated display indicating number of puffs taken and remaining battery charge), a touchpad to provide user inputs, and further provide haptic feedback and audible alerts to indicate certain statuses (e.g. low battery, end of puff). Device B may also support recharging of the battery via a wired electrical connector interface (e.g. a USB-C cable). Device C is a more complex device again which supports the functions of Device B, with wireless instead of wired charging (e.g. via induction), and further supports wireless communications via a Bluetooth Low Energy (BLE) data transfer protocol. Devices B and C may be considered reusable devices, which can be recharged, and may be refilled with aerosol generating material (e.g. via switching of disposable cartridges). The example of aerosol provision systems is only for illustration, and this concept can be generalised to a set of other devices, with different functions to be supported.

Thus the total/global function set required to support any of Devices A, B, and C, comprises 8 functions, namely: control of current to aerosol generator, control of display element(s), control of haptic feedback element(s), control of audible feedback element(s), monitoring of user input interface, control of wireless communications module, control of charging of power supply, and monitoring of environmental/operating parameter. It will be appreciated some of the functions are either present or not-present in a given device/context, and other functions, where present, have a plurality of different potential ‘enabled’ operating statuses. For example, in Device A, the function of ‘control of display element(s)’ is carried out according to a simple single-LED mode, whereas in Devices B and C, control of the same function is carried out according to a pixilated display unit mode; and in Device B, control of the charging function is carried out in a wired mode, whereas in Device C, control of the same function is carried out in a wireless mode.

To support each of the potential use contexts (e.g. Devices A, B, and C, in the example above), an ASIC package 200 may be configured to be set into any one of at least 3 different target functional configurations, wherein each functional configuration comprises a different set of operating statuses associated with respective functional units/blocks which provide control logic associated with each function. The respective operating statuses for functional units of the ASIC package, associated with a suitable target configuration for each of Devices A, B, and C, from the example above, are indicated in Table 2 below.

TABLE 2

| Functional Unit | Configuration A | Configuration B | Configuration C |
|---|---|---|---|
| control of current to | ENABLED | ENABLED | ENABLED |
| aerosol generator | | | |
| control of display | ENABLED | ENABLED | ENABLED |
| element(s) | (single LED) | (pixilated) | (pixilated) |
| control of haptic feedback | DISABLED | ENABLED | ENABLED |
| element(s) | | | |
| control of audible | DISABLED | ENABLED | ENABLED |
| feedback element(s) | | | |
| monitoring of user input | DISABLED | ENABLED | ENABLED |
| interface | | (touchpad) | (touchpad) |
| control of wireless | DISABLED | DISABLED | ENABLED |
| communications module | | | (BLE) |
| control of charging of | DISABLED | ENABLED | ENABLED |
| power supply | | (USB-C) | (wireless) |
| monitoring of | ENABLED (heater | ENABLED (heater | ENABLED (heater |
| environmental/operating | temperature) | temperature) | temperature) |
| parameter | | | |

Typically, provision of a controller unit/controller units to support functions of Devices A, B, and C, with their different sets of functions, and different associated operating statuses (including sub-statuses where enabled), would usually require either (i) different device-specific software/firmware loaded onto a common MCU which could be utilised in each device (with resulting lack of hardware optimisation, and potentially higher per-unit cost); (ii) different device-specific software/firmware loaded onto different MCUs specified for each respective device; or (iii) design of a different ASIC for each respective device. The inventor has recognised that by providing a shared ASIC package design which has the ability to support any of the required functions of a plurality of devices (e.g. Devices A, B, and C), via provision of functional units configured to support the entire set of required functions across all devices, the same ASIC package can be used in any of the devices, with the functional configuration which defines the operating status of each functional block being configured differently for each device type according to approaches set out herein. Thusthe optimisation benefits of using an ASIC can be realised, along with the flexibility of supporting multiple use cases, which are typically only realisable at present with an MCU or FPGA.

Thus design of a configurable ASIC package 200 according to the present disclosure first requires definition of the potential use cases and their associated functions (e.g. a plurality of target devices in which the ASIC package may be used, and the set of functions the ASIC package will be required to support in each target device). This step defines the total function set for the ASIC package. Next, a set of operating statuses is defined, on a per-function basis, by determining for each function the different implementation details of the function in the plurality of use cases (e.g. devices). For example, some functions will always be enabled (such as ‘control of current to aerosol generator’ in each of Devices A, B, and C), and some may be either enabled or disabled. Any of the ‘enabled’ operating status may have sub-statuses defined, as described above. Typically, different ‘enabled’ statuses are defined at least in part by the component(s) to which the ASIC package is connected within the device in order to support the function in each of the use cases. Thus, for example, as set out above, the control logic and number of input/output terminals required to support the function of ‘control of display element(s)’ will differ depending on whether the display element(s) comprise one or more LEDs, or comprise a pixilated display; and the control logic and number of input/output terminals required to support the function of ‘control of charging of power supply’ will differ depending on whether the charging is implemented via a wired connection (e.g. USB-C) or a wireless connection (e.g. via inductive charging hardware). Depending on operating status of a given functional unit of the ASIC, it may be configured to receive and provide different signals from/to different ones of the terminals of the ASIC package, with different characteristics (e.g. in terms of voltage, current, and frequency, and whether the signals are analogue or digital signals). These requirements can be determined in the usual manner known to the skilled person, based on known principles of ASIC design.

Once the total/global set of functions required to support any of the different use contexts/devices is defined, the required set of functional units and associated operating statuses required to support each function of the global function set can also be defined. Where a functional unit comprises more than one ‘enabled’ operating status, wherein each operating status comprises different control logic (in terms of number of input/output terminals associated with operation, and/or the processing flow, and/or the characteristics of input/output signals), the specific control logic for each different ‘enabled’ operating status of a given functional unit may be configured by providing different hardware (e.g. a different functional sub-unit) to support each operating status, or by providing different software/micro-code for each functional unit, to selectably run on the same functional unit hardware, with the software/micro-code to be used being different depending on which enabled operating status is to be supported. The implementation of each functional unit of the ASIC package (e.g. in terms of design and fabrication) to support the required functions and associated operating statuses may be carried out according to approaches for ASIC design known to the skilled person, and as described in further detail herein. Thus the implementation of each functional unit and its interconnections (if present) with other functional units, may typically be effected via a register-transfer level (RTL) design step (e.g. using Verilog or VHDL), followed by a logic synthesis stage, leading to placement and routing stages. The number of terminals of the ASIC package 200 will typically be defined during this design stage, based on the number of input/output channels required to support each functional unit, and the degree to which functional units may be able to share different input/output channels.

What is considered significant in embodiments of the present disclosure is that the ASIC package 200 may be configured to be set into a given one of a plurality of possible target functional configurations This may be achieved in a reversible or non-reversible manner. As set out further herein, each functional configuration is associated with a different set of operating statuses associated with each of the plurality of functional units of the ASIC package, and this ‘setting’ of the ASIC package into a functional configuration comprises modifying the ASIC package, which by default may be manufactured as a ‘master’ ASIC package having all functional units operational/enabled for use, or non-operational/disabled for use, so that the operational status of at least one functional unit is changed from enabled to disabled, or from a first enabled sub-status to a second enabled sub-status. Typically, in all embodiments of the present disclosure, this modification may be effected post-manufacture/fabrication of the ASIC package. This may be effected as processing stage following, for example, photolithographic fabrication of the ASIC control logic, or as a processing stage following delivery of master ASIC packages to a customer, but before assembling the ASIC packages into devices, or as a step after a given ASIC package is assembled into a device.

In a first set of embodiments, the ASIC package 200 can be set into a given one of the plurality of target functional configurations in a non-reversible manner (in other words, in a manner which cannot be reversed without further physical modification of the ASIC package). In a first set of embodiments, this is effected via physical manipulation of at least one structural element of the ASIC package. For example, one or more fusible links may be defined on electrical interconnects between (i) one or more functional units and the input/output terminals to which they are directly or indirectly connected, and/or (ii) one or more of the functional units (e.g. electrical interconnects allowing signals to be routed between functional units, where a processing path involves a chain of control logic implemented by two or more functional units).

The determination of locations for the fusible links may be defined in the routing stage. The number of fusible links and their positions on electrical paths of the ASIC (e.g. within functional units, on interconnects between them, and/or on interconnects between terminals of the ASIC package 200 and the functional units) are defined such that that each of the plurality of potential functional configurations of the ASIC package can be expressed in terms of a different pattern of fusible links to be ruptured to provide a routing network which provides control logic supporting the required operating statuses associated with each of the functional units of the ASIC package. Thus in the example above, rupturing a first subset of fusible links provides a ‘Configuration A’ ASIC package, suitable for supporting functions of Device A, in which the functional units associated with control of current to an aerosol generator and monitoring or heater temperature are enabled, and the functional unit associated with control of a display element is in a ‘single LED’ mode (e.g. a functional sub-unit with control logic for supporting visual feedback via a single LED is enabled, and a second functional sub-unit with control unit for supporting visual feedback via a pixilated display is disabled). All other functional units listed in Table 2 are disabled. Thus the rupturing the first set of fusible links associated with ‘Configuration A’ provides a routing path for signals within the ASIC package 200 which in effect causes the ASIC package to operate as if it only comprised functional units associated with the functions supported by Device A (as listed in Table 1). Similarly, rupturing a second subset of the fusible links provides a ‘Configuration B’ ASIC package, suitable for supporting functions of Device B, and rupturing a third subset of the fusible links provides a ‘Configuration C’ ASIC package, suitable for supporting functions of Device C. The pattern of fusible links to be ruptured for each functional configuration may result in functional units required to be disabled in the functional configuration being electrically isolated from all the terminals of the ASIC package, or from receiving electrical power, or may alter the manner in which any given functional unit is connected to respective ones of the terminals and/or other functional units, in order to modify the control logic of the ASIC package when the links are ruptured. By way of a non-limiting example, a given ASIC package may comprise a functional unit configured to provide a charging function as described further herein. In the ASIC package in the as-manufactured state, electrical interconnects may connect this charging functional unit to a master control functional unit configured to trigger charging and set charging parameters for the charging functional unit, and electrical interconnects may connect the charging functional unit to one or more power supply terminals to receive external power (e.g. from a charging connector), and to one or more battery terminals to provide charging current to the battery. When the ASIC package is configured for a device of Device D, where charging is not required, a pattern of fusible links disposed on these sets of electrical interconnects may be ruptured. Isolating an un-needed functional unit in this manner may provide safety benefits, in preventing triggering of un-needed functions, and also reduce power draw of the ASIC package by reducing the power density of the ASIC package.

Where the target configuration of the ASIC package is set by physical manipulation of one or more structural elements of the ASIC package, this may therefore may comprise breaking of at least one fusible link. In some embodiments, the ASIC package is configured such that the fusible links are accessible for rupturing after the ASIC package is fabricated (e.g. via a photolithography fabrication process), via a process in which conductive material is removed from a portion of the ASIC package to break an existing current path between a predefined pair of electrical nodes (i.e. a fusible link position). The conductive material at a one or more fusible link positions may be removed via a mechanical process (e.g. scraping or cutting of material), a chemical etching process, or a laser ablation process. Any of these processes may be carried out as a ‘finishing’ process once the die for the ASIC package has been fabricated to producing ‘master’ ASIC packages, which can then be configured into any of a Configuration A, B, or C, ASIC package via a finishing step comprising the removal of conductive material comprising one or more fusible links, to arrive at an ASIC package with a specific target functional configuration.

In some embodiments, the ASIC package comprises control logic (e.g. a configuration-setting functional unit) configured to cause a current to be applied through the at least one fusible link suitable to cause the breaking of the fusible link. Thus in response to an input signal received at one or more terminals of a ‘master’ ASIC package, indicating to the configuration-setting functional unit a target configuration for the ASIC package, the configuration-setting functional unit is configured to cause current at a suitable power level to be passed through one or more target fusible links to cause fusible link rupture, where the set of fusible links to be ruptured is dependent on the target configuration, as described above. Thus in response to a predefined control signal supplied to at least one terminal (e.g. across a control terminal and a ground terminal such as V_{ground}), applied, for example, after fabrication of a master ASIC package where all fusible links are unruptured, a configuration-setting functional unit (where included) routes a rupturing current to particular circuit paths of the ASIC package to induce a pattern of ruptured fusible links associated with the target functional configuration with which the predefined control signal is associated. In other embodiments, the fusible link positions may be substituted for arrangements of diodes, wherein the ASIC package is configured to be set into the target functional configuration by the configuration-setting functional unit being configured to transmit control signals to set the conduction state(s) of at least one of the one or more diodes or other switch elements (e.g. solid state switches such as field-effect transistors) to either allow current to pass, or prevent passing of current. In some embodiments where the fusible link positions are substituted for switch elements, a functional unit of the ASIC package responsible for setting the ASIC package configuration may be pre-configured with a register indicating a set of switch element states to implement (either to open or closed) for each of the potential target configurations, by providing appropriate control signals (e.g. gate voltages where the switch elements are field-effect transistors) to modify their states. The functional unit may be configured apply a different configuration of switch states (i.e. via a specific pattern of switch control signals) based on detecting a particular voltage at a control terminal connected to the functional unit by appropriate electrical interconnects within the ASIC package, where the register associates configurations with predefined ranges of voltage. The control terminal may in some embodiments comprise a terminal to be connected to a battery, or to a power controller of the device in which the ASIC package is to be used (e.g. a power controller which regulates, for example by stepping up or down, the battery voltage). These embodiments may be considered to be similar to those comprising fusible links, except that modification of the circuit paths within the ASIC package is effected by reversibly switching the states of diodes (or other switch elements, such as field-effect transistor (FET) switches) to on or off, instead of irreversibly setting the states of fusible links to be broken or broken.

In other embodiments, the modification of electrical connectivity of links between circuit elements of the ASIC package effected to set a master ASIC package into one of a plurality of potential target configurations is achieved by configuring a set of nodes at locations on the circuitry of the ASIC package at which conductive material can be added to complete a circuit path. The locations of the nodes can be defined such that adding conductive material completes one or more circuit path element disposed at interconnects between (i) one or more functional units and the input/output terminals to which they are directly or indirectly connected, and/or (ii) one or more of the functional units (e.g. electrical interconnects allowing signals to be routed between functional units, where a processing path involves a chain of control logic implemented by two or more functional units). The determination of locations for the nodes may be defined in the routing stage, as with the determination for locations of fusible links described above. The number of nodes and their positions on electrical paths of the ASIC (e.g. within functional units, on interconnects between them, and/or on interconnects between terminals of the ASIC package 200 and the functional units) are defined such that that each functional configuration of the ASIC package can be expressed in terms of a different pattern of nodes at which conductive material is to be added. Thus in the example above, providing conductive material at a first subset of node locations provides a ‘Configuration A’ ASIC package, suitable for supporting functions of Device A, in which the functional units associated with control of current to an aerosol generator and monitoring or heater temperature are enabled, and the functional unit associated with control of a display element is in a ‘single LED’ mode (e.g. a functional sub-unit with control logic for supporting visual feedback via a single LED is enabled, and a second functional sub-unit with control unit for supporting visual feedback via a pixilated display is disabled). All other functional units listed in Table 2 are disabled. Thus the provision of conductive material at a first subset of node locations associated with ‘Configuration A’ provides a routing path for signals within the ASIC package 200 which in effect causes the ASIC package to operate as if it only comprised functional units associated with the functions supported by Device A (as listed in Table 1). Similarly, the provision of conductive material at a second subset of node locations leads to a ‘Configuration B’ ASIC package, suitable for supporting functions of Device B, and the provision of conductive material at a third subset of node locations leads to a ‘Configuration C’ ASIC package, suitable for supporting functions of Device C. Thus, in some embodiments of the present disclosure, the physical manipulation of the at least one structural element of the ASIC package comprises adding conductive material to a portion of the ASIC package to form a new current path between a predefined pair of electrical nodes. The conductive material may be added via any approach known to the skilled person, such as, for example, by soldering or other deposition process. In some embodiments, the approach of providing nodes at which conductive material may be added to complete circuit paths is combinable with the fusible link approaches described herein, such that a master ASIC package comprises both fusible links, and nodes at which conductive material may be added, and each of the plurality of potential target configurations is associated with a different pattern of fusible links to be ruptured and/or nodes at which conductive material is to be added to arrive at a routing path for electrical signals within the ASIC package which provides control logic corresponding to enablement/disabling of the relevant functional units associated with a respective use context/device in which the ASIC package 200 is to be implemented. In any of these embodiments, the pattern of fusible link ruptures and/or conductive material addition nodes in effect allows modification (via fusible link rupture and/or conductive material addition) of the routing of electrical interconnects between functional units, in order to modify the hardware control logic of the ASIC package between different configurations supporting different operating states of different functional units selected from the global set of functional units for which hardware control logic is provided on the semiconductor die.

In some embodiments of the present disclosure, the ASIC package 200 comprises a memory element, and further comprises control logic configured to store a value in the memory element, the value being one of a set of predefined values respectively associated with the plurality of functional configurations, wherein the control logic is further operable to set as the functional configuration a one of the plurality of different functional configurations which is associated with the one of the predefined values. The control logic may be implemented via a configuration-setting functional unit comprised in the ASIC package, as described further herein, configured to receive an input signal from an external source to indicate a target configuration for the ASIC package, and based on a step of determining the indicated functional configuration, to set as a value or data package in the memory element a corresponding value/indicator uniquely identifying the target configuration. Based on the specific value/indicator stored in the memory element, the configuration-setting functional unit is configured to set the target configuration of the ASIC package via one of the approaches set out herein (i.e. non-reversibly, via transmission of rupturing signals to rupture a predefined pattern of fusible links; or reversibly, via transmission of signals to reversibly set the conduction state of a set of diodes or other switchable elements). The memory element (or a further memory element) typically stores information indicating the pattern of fusible elements to be ruptured, or switch states to be changed, in order to arrive at each one of the plurality of supported functional configurations.

In embodiments where the setting of the target functional configuration of the ASIC package is effected by a configuration-setting functional unit of the ASIC package, in response to detection of a predefined signal by the configuration-setting functional unit, said predefined signal uniquely identifying one of a plurality of potential target configurations, the configuration-setting functional unit is configured in one or more of a plurality of ways to detect such a predefined signal. For example, the ASIC package (i.e. a configuration-setting functional unit of the ASIC package) may be configured to set the selected functional configuration via detection of at least one predefined characteristic of an input signal applied to one or more of the plurality of terminals/pins of the ASIC package, wherein a functional configuration to be set by the ASIC package is associated with the predefined characteristic. In these embodiments, the predefined characteristic may comprise a combination (e.g. a pattern) of one or more of the plurality of pins/terminals at which the input signal is detected, and wherein the ASIC package is configured with control logic operable to set as the functional configuration a particular one of the plurality of different functional configurations which is associated with a specific combination of the one or more of the plurality of terminals at which the input signal is detected. In some embodiments, at least one of the one or more of the plurality of terminals comprises at least one control terminal of the ASIC package which is not associated with the control by the plurality of functional blocks of any of the aspects of operation associated with the use context/device in which the ASIC is to be implemented.

Thus the control terminal may be a dedicated terminal for receiving of control signals used to indicate a target configuration for the ASIC package, and the plurality of terminals comprises the control terminal and a ground, GND, terminal (e.g. V_{ground}). In addition, or alternatively, the predefined characteristic of the signal may comprise a voltage detected at the one or more of the plurality of terminal, and wherein the ASIC package is configured with control logic operable to set as the functional configuration a one of the plurality of different functional configurations which is associated with a range of voltage associated with the voltage of the input signal. In some instances, the control signal is applied across the V_{supply} and V_{ground} terminals, and the respective ranges of voltage associated with respective target configurations are set to correspond to (i.e. include) the value of battery/power source voltage (e.g. when fully charged), or range of operating voltages, associated with respective devices/operating contexts in which the ASIC may be used. Thus, as a non-limiting example, if a Device A provides a supply of power to the ASIC package at a voltage of between 4 to 5 volts, and a Device B provides a supply of power to the ASIC package at a voltage of between 5.5 to 6.5 volts, and a Device C provides a supply of power to the ASIC package at a voltage of between 7 to 8 volts, the ASIC package may be configured to set the target configuration to Configuration A if the supply voltage is detected as being between 4 to 5 volts, Configuration B if the supply voltage is detected as being between 5.5 to 6.5 volts, and to Configuration C if the supply voltage is detected as being between 7 to 8 volts. The ASIC package may alternatively or additionally be configured to detect electrical parameters (e.g. inductance, impedance, resistance, capacitance) of components electrically connected to its terminals, and/or the pattern of terminals to which components are electrically connected, and set a specific target configuration based on the determined values of electrical parameters and/or pattern of terminals at which electrical connections to components are detected. For example, as a non-limiting example, if a Device A comprises an aerosol generator comprising a heater with a resistance of 0.8 ohms, and a Device B comprises an aerosol generator comprising a heater with a resistance of 1.3 ohms, and a Device C comprises an aerosol generator comprising a heater with a resistance of 2.2 ohms, the ASIC package may be configured to set the target configuration to Configuration A (i.e. via provision of a signal to the functional-configuration setting unit) if resistance of a heater connected to a functional unit responsible for control of current to an aerosol generator detects a resistance of a connected component of between 0 and 1 ohms, to set the target configuration to Configuration B if the resistance is between 1 and 2 ohms, and to set the target configuration to Configuration C if the resistance is between 3 and 4 ohms. In some embodiments, the predefined characteristic of the signal comprises a signal pattern detected at one or more of the plurality of terminals, and the ASIC package is configured with control logic (e.g. a functional-configuration setting functional unit) operable to set as the functional configuration a one of the plurality of different functional configurations which is associated with a signal pattern of the input signal. For example, the signal may comprise a power supply signal received from a power source, and the pattern may comprise a frequency of the signal.

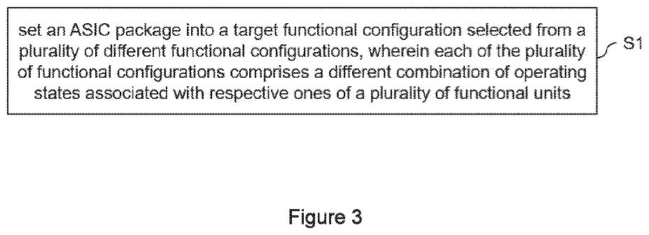

Thus there has been described an application specific integrated circuit, ASIC, package, for use in an electrical or electronic device, the ASIC package comprising: a plurality of functional units, wherein each of the plurality of functional units is configured with control logic operable to provide a discrete monitoring and/or control function associated with an aspect of operation of the electronic aerosol provision system, and wherein an operating status of each of the functional units may be independently configurable into one of an enabled and non-enabled operational state; and a plurality of terminals, comprising a plurality of power supply terminals and a plurality of input and/or output terminals, wherein each one of the plurality of input and/or output terminals is connected to at least one of the plurality of functional units. With reference to FIG. 3, a method is also provided of operating such an ASIC package, wherein the method comprises, in a first step, S1, setting the ASIC package into a target functional configuration selected from a plurality of different functional configurations, wherein each of the plurality of functional configurations comprises a different combination of operating states associated with respective ones of the plurality of functional units. Step S1 may be carried out in accordance with approaches described herein.

### Further Features of Configurable and Non-Configurable ASIC Packages

It will be appreciated that whilst the present disclosure describes ASIC packages which are configured to be set into a target functional configuration selected from a plurality of different functional configurations, wherein each of the plurality of functional configurations comprises a different combination of operating states associated with respective ones of the plurality of functional units, any of the ASIC packages described herein may alternatively be provided without being configurable in this manner.

As described further herein, where an ASIC package is provided a ‘configurable ASIC’, which is configured to be set into a target functional configuration selected from a plurality of different functional configurations, this may comprise the setting of ‘disabled’ or ‘enabled’ operating states for respective functional units. However, this may additionally or alternatively comprise defining a plurality of ‘enabled operating states for any given functional unit, where each of the ‘enabled’ operating states is configured by loading different software/micro-code to run on the given functional unit, or different parameters (e.g. in the form of matrices), to be selectively accessed by the same functional unit hardware, with the software/micro-code/parameters/matrices to be run and/or accessed being different depending on which ‘enabled’ operating status of the plurality of ‘enabled’ operating statuses is configured for use. Different ones of a plurality of ‘enabled’ operating states for a given functional unit may be implemented by the provision of a plurality of parameter values or parameter sets for use in the control logic of a given functional unit, with the parameter or set of parameters to be used being different depending on which enabled operating status is to be supported. Thus where a functional unit implements control logic in which a parameter or set of parameters is used (where the parameters may be, for example, threshold values or coefficients for use in functions), different ‘enabled’ states into which the functional unit may be configured may be associated with the provision of a different parameter or parameter set to the functional unit in the form of a plurality of parts of a matrix stored in memory of the ASIC package, or a plurality of matrices so stored, having a one-to-one mapping with each ‘enabled’ state.

A parameter or parameter set (represented, for example, as a matrix or other data structure) may be read from a memory element of the ASIC package as described further herein, which may be a memory element accessible by multiple functional units (for example, where a single parameter or parameter set is relevant to control logic of a plurality of functional units), or may be a memory element (e.g. a register) associated with the specific functional unit implementing the control logic to which the parameter or parameter set relates. In embodiments of the disclosure, different ‘enabled’ states for a given functional unit may be set by triggering the functional unit to read a different predefined parameter or parameter set (e.g. in the form of one or more matrices) from a memory element (e.g. a RAM element, flash memory, or a register) in dependence on which of a predefined set of ‘enabled’ states is to be set by the target configuration. This triggering may be controlled, as set out further herein, by a functional-configuration setting functional unit of the ASIC package as described further herein). Each of a plurality of ‘enabled’ states for a given functional unit may be mapped to a different parameter or parameter set in a one to one mapping, or more than one ‘enabled’ state may be mapped to the same parameter or parameter set. In embodiments of the present disclosure, a parameter or parameter set may be configured as one or more matrices of values stored in a memory element such as a register. Such matrices may be one-, two-, three-, four- or higher-dimensional, depending on the number of variables and parameters operated upon by the control logic of a given functional unit).

It will thus be appreciated that where an ASIC package is configured to be set into a target functional configuration selected from a plurality of different functional configurations, this may comprise hardware alterations to the ASIC package to set a specific target configuration (for example, by adding or removing current paths/interconnects within and/or between functional units of the ASIC package (as described herein), but may alternatively or additionally comprise modifying software/code and/or parameters (e.g. represented as matrices) to be used in implementing control logic on the same hardware, to set a specific target configuration, without making physical changes to the ASIC package hardware to set the ASIC package into a target configuration from among of a plurality of predefined configurations. In some examples, setting a target configuration may involve a ‘physical configuration’ change only, a ‘software/parameter configuration’ change only, or both physical and software/parameter changes may be made to the ASIC package to set a target configuration. It will be appreciated that whilst aspects of the present disclosure relate to a ‘configurable ASIC’, this disclosure is also directed to provision of a ‘non-configurable ASIC’ which is not configured to be set into a target functional configuration selected from a plurality of different functional configurations by setting of ‘disabled’ or ‘enabled’ operating states for respective functional units. Thus an aspect of the present disclosure is the provision of a non-configurable ASIC comprising any feature and/or functionality of ASIC packages described herein (except for those directly related to setting an ASIC into one of a plurality of target configurations). A configurable or non-configurable ASIC according to the present disclosure may used to implement control logic in any electrical/electronic device, including handheld consumer electronic devices (e.g. digital cameras, digital video cameras, GPS units, telephones, watches, digital music players), household appliances (e.g. washing machines, dryers, fridges, freezers, dishwashers, smart speakers, microwaves, toasters, coffee makers, or blenders), vehicles (e.g. cars, aircraft, spacecraft, satellites, drones/UAVs, or trains), and computer peripherals and/or modules in computer systems (e.g. motherboards, hard drives, sound or graphics cards, wireless telecommunications controllers, or network switches), or any other electrical/electronic device known to the skilled person.

### Safety Functions

In embodiments of the disclosure, an ASIC package may be configured to incorporate one or more functional units implementing functions which may be considered related to device safety. For example, such safety-related functions may relate to determining that at least one electrical parameter (e.g. a voltage, current, power, resistance, inductance, capacitance, or a function of at least one of these parameters, such as a rate of change) is outside a predefined range or threshold. Safety-related functions may also relate to determining that at least one temperature parameter (e.g. a temperature of a heater, a power supply, a switch, or one or more functional units of the ASIC, or function of at least one of these parameters) is outside a predefined range or threshold. A functional unit implementing control logic related to device safety (e.g. by detecting unsafe device states and/or triggering device protection protocols on the basis of such detection, and/or supporting the functionality of functional units which provide these two functions) may be referred to herein as a safety-related functional unit. It will be appreciated that a safety-related functional unit may be configured and fabricated according to any of the approaches described herein for configuration and fabrication of functional units of an ASIC package more generally, for example in terms of the configuration of control logic, physical implementation within the ASIC package, provision of interconnects to terminals and/or other functional units, and where relevant the provision of modifiable software (e.g. firmware/microcode) and or parameters or parameter sets (e.g. in the form of matrices) to introduce flexibility into the control logic of the functional unit(s). Furthermore, it will be appreciated that any of the safety-related functional units described herein may be implemented in a configurable ASIC package as described herein, or in a non-configurable ASIC package.

Accordingly, in embodiments of the present disclosure, a configurable or non-configurable ASIC package may be provided with one or more (and in some instances all) of the following safety-related functional units. It will be appreciated that where a given ASIC package is configurable, functionality of any number of the safety-related functional units described herein may be combined into a single safety-related functional unit which is configured to be set into a target functional configuration selected from a plurality of different functional configurations, wherein each of the plurality of functional configurations comprises a different combination of operating states associated with respective ones of the plurality of functional units. Thus each of the discrete functions below may be implemented in a separately configurable functional unit, or any two or more of the discrete functions below may be implemented in a separately configurable functional unit. In some embodiments, all of the safety functions (for example, all of the functions below) may be implemented in a single, ‘master’ safety-directed functional unit. An ASIC package comprising any combination of the functional units described below may be provided as a ‘configurable ASIC package’, or as a ‘non-configurable ASIC package’.

### Over-Current Protection (OCP) Functional Unit

In embodiments of the present disclosure, an ASIC package may be provided with an over-current protection (OCP) functional unit. The OCP functional unit may be directly or indirectly interconnected with any other functional unit of the ASIC package, to receive inputs from and provide outputs to other functional units such as the PCM functional unit described herein, providing tight integration of inter-related functionality within the ASIC package. An OCP functional unit determines one or more current values, or values dependent on current, relating to operating of a device in which the ASIC package is to be used (herein referred to as a ‘host device’) and/or the ASIC package itself. The OCP functional unit may comprise an ADC for conversion of current signals applied to terminals of the ASIC package, or nodes within the ASIC package, or receive digital signals representing one or more current values from another functional unit, such as an ADC functional unit as described herein. The current signals to be measured may relate to, for example, a charging current used to charge a battery of the host device, or a current on a circuit used to power a load of the host device (e.g. a heater), or a current on a current path within the ASIC package itself. Current values may be received from another safety-related functional unit (e.g. a charging, PMIC or PMC functional unit as described herein).

An OCP functional unit is provided with control logic configured to detect an over-current condition on the basis of current measurements, and provide an output to at least one another functional unit trigger a safety function on the basis of this determination. In embodiments, the control logic of the OCP functional unit is configured to compare at least one current measurement to a predefined threshold, and/or compare a function of at least one current measurement (e.g. a rate of change of current) to a predefined threshold. The predefined threshold may be a single value (e.g. where the OCP functional unit is implemented in a non-configurable ASIC). Where the OCP functional unit is implemented in a configurable ASIC, a plurality of thresholds (represented, for example, as one or more matrices) may be mapped to different ‘enabled’ states which may be set for the OCP functional unit, using approaches described herein for configuration of different parameters/parameter sets mapped to different ‘enabled’ states of a functional unit. If the control logic of the OCP functional unit determines a current value exceeds a predefined threshold, it is configured to trigger a safety function. For example, the OCP functional unit may transmit a signal to a PMC, PMIC, and or dual switch (dual-SW) functional unit as described herein, to trigger one of the following actions:
Suspension of a power storage element charging procedure (for example by triggering a dual switch (dual-SW) functional unit to open one or more switches on a charging current path disposed between a charger for the host device, and a battery or other power storage element of the host device, as described in the ‘safety switching’ section herein).
Suspension of a power storage element discharge procedure (for example by triggering a dual-SW functional unit to open of one or more switches on a current path disposed between a battery or other power storage element of the host device and a load (such as a heater) as described in the ‘safety switching’ section herein).
Initiation of a device shut-down procedure of the host device, for example by triggering a processing core (i.e. ASIC core) of the ASIC package to power down, and/or by triggering an ASIC package master control unit as described herein to implement a shut-down of the host device.

The OCP functional unit may trigger a reset or clearing of one of the above safety functions if a subsequent current value is determined to be below one or more predefined thresholds (for example, by triggering a PMIC or PMC functional unit to un-suspend/resume a charging procedure, and/or triggering a PC functional unit to enable supply of power to a load of the host device).

### Over-Voltage Protection (OVP) Functional Unit

In embodiments of the present disclosure, an ASIC package may be provided with an over-voltage protection (OVP) functional unit. The OVP functional unit may be directly or indirectly interconnected with any other functional unit of the ASIC package, to receive inputs from and provide outputs to other functional units such as the PCM and PMIC functional units described herein, providing tight integration of inter-related functionality within the ASIC package. An OVP functional unit receives as an input a reading of one or more voltage values, or values dependent on voltage, relating to operation of the host device. The OVP functional unit may comprise an ADC for conversion of voltage signals applied to terminals of the ASIC package, or nodes within the ASIC package, or receive digital signals representing one or more voltage values from an ADC functional unit as described herein. The voltage signals to be measured may relate to, for example, a charging voltage used to charge a battery of the host device, or a voltage across components of a load of the host device configured to be powered by the ASIC package (for example a heater, and/or shunt resistor), or a voltage across one or more components within the ASIC package itself. Voltage values may be received from another safety-related functional unit (e.g. a charging, PMIC or PMC functional unit as described herein).

An OVP functional unit is provided with control logic configured to detect an over-voltage condition on the basis of voltage measurements, and provide an output to at least one another functional unit trigger a safety function on the basis of this determination. In embodiments, the control logic of the OVP functional unit is configured to compare at least one voltage measurement to a predefined threshold, and/or compare a function of at least one voltage measurement (e.g. a rate of change of voltage) to a predefined threshold. The predefined threshold may be a single value (e.g. where the OVP functional unit is implemented in a non-configurable ASIC). Where the OVP functional unit is implemented in a configurable ASIC, a plurality of thresholds (represented, for example, as one or more matrices) may be mapped to different ‘enabled’ states which may be set for the OVP functional unit, using approaches described herein for configuration of different parameters/parameter sets mapped to different ‘enabled’ states of a functional unit. If the control logic of the OVP functional unit determines a voltage value exceeds a predefined threshold, it is configured to trigger a safety function. For example, the OVP functional unit may transmit a signal to a PMC, PMIC, and or dual switch (dual-SW) functional unit, to trigger a safety function, such as one of the actions described herein in relation to the OCP functional unit.

The OVP functional unit may trigger a reset or clearing of one of the above safety functions if a subsequent voltage value is determined to be below the predefined threshold (for example, by triggering a PMIC or PMC functional unit to un-suspend/resume a charging procedure, and/or triggering a PC functional unit to enable supply of power to a load of the host device).

### Ultra-Low-Voltage Protection (ULVP) Functional Unit

In embodiments of the present disclosure, an ASIC package may be provided with an ultra-low-voltage protection (ULVP) functional unit. The ULVP functional unit may be directly or indirectly interconnected with any other functional unit of the ASIC package, to receive inputs from and provide outputs to other functional units such as the PCM and PMIC functional units described herein, providing tight integration of inter-related functionality within the ASIC package. An ULVP functional unit receives as an input a reading of one or more voltage values, or values dependent on voltage, relating to operating of the device in which the ASIC package is implemented. The ULVP functional unit may comprise an ADC for conversion of voltage signals applied to terminals of the ASIC package, or nodes within the ASIC package, or receive digital signals representing one or more voltage values from an ADC functional unit as described herein. The voltage signals to be measured may relate to, for example, a charging voltage used to charge a battery of the host device, or a voltage across components of a circuit used to power a load of the host device (for example a heater, and/or resistor), or a voltage across one or more components within the ASIC package itself. Voltage values may be received from another safety-related functional unit (e.g. a charging, PMIC or PMC functional unit as described herein).

An ULVP functional unit is provided with control logic configured to detect an under-voltage condition on the basis of voltage measurements, and provide an output to at least one another functional unit trigger a safety function on the basis of this determination. In embodiments, the control logic of the ULVP functional unit is configured to compare at least one voltage measurement to a predefined threshold, and/or compare a function of at least one voltage measurement (e.g. a rate of change of voltage) to a predefined threshold. The predefined threshold may be a single value (e.g. where the ULVP functional unit is implemented in a non-configurable ASIC). Where the ULVP functional unit is implemented in a configurable ASIC, a plurality of thresholds (represented, for example, by one or more matrices) may be mapped to different ‘enabled’ states which may be set for the OVP functional unit, using approaches described herein for configuration of different parameters/parameter sets mapped to different ‘enabled’ states of a functional unit. If the control logic of the OVP functional unit determines a voltage value exceeds a predefined threshold, it is configured to trigger a safety function. For example, the OVP functional unit may transmit a signal to a PMC, PMIC, and or dual switch (dual-SW) functional unit, to trigger a safety function, such as one of the actions described herein in relation to the OCP functional unit.

The ULVP functional unit may trigger a reset or clearing of one of the above safety functions if a subsequent voltage value is determined to be above the predefined threshold (for example, by triggering a PMIC or PMC functional unit to un-suspend/resume a charging procedure, and/or triggering a PC functional unit to enable supply of power to a load of the host device).

### Temperature Management™ and Over Temperature Protection (OTP) Functional Unit(s)

In embodiments of the present disclosure, an ASIC package may be provided with a temperature management (TM) functional unit. The TM functional unit may be directly or indirectly interconnected with any other functional unit of the ASIC package, to receive inputs from and provide outputs to other functional units such as the PCM and PMIC functional units described herein, providing tight integration of inter-related functionality within the ASIC package. A TM functional unit receives as an input a reading of one or more temperature values, or values dependent on temperature, relating to operating of the device in which the ASIC package is implemented. The TM functional unit may comprise an ADC for conversion of analogue temperature measurement signals received from one or more temperature sensors, or may receive temperature measurements from an ADC functional unit configured to perform conversion of temperature measurement signals received from one or more temperature sensors, or may receive temperature measurements from a temperature measurement functional unit comprising temperature measurement hardware. The temperature signals to be measured may relate to, for example, an ambient temperature to which the host device is exposed, a temperature of a battery or other power storage element of the host device, and/or a temperature of a heater comprised in the host device, and/or a temperature of the ASIC package.

In embodiments, the TM functional unit may receive temperature values associated with the temperature of a battery (noting this term is used to apply to any power storage element of the host device), and/or temperature values associated with the temperature of a heater (for example a heater configured for generation of aerosol), and/or temperature values associated with a temperature of the ASIC package itself. In any of these cases, the temperature measurements may be made out by temperature sensor circuitry situated in the host device external to the ASIC package (for example, connected to the TM functional unit via an I2C functional unit), and/or temperature sensing circuitry comprised in the ASIC package itself. For example, temperature sensing circuitry (implementing, for example, thermocouple or IR sensor functionality) may be implemented in a temperature measurement functional unit (which may be referred to herein as an over temperature protection (OTP) functional unit) connected to the TM functional unit, and/or integrated into the TM functional unit. This integration of one or more, and in some cases all temperature sensors of a host device into an ASIC package, may be advantageous in eliminating the requirement for one or more temperature sensors to be provided external to the ASIC package in the host device. This may provide a simpler, more efficient, more easily assembled, and/or more robust device, at lower cost. Where an ASIC package of the present disclosure comprises one or more OTP functional units, the ASIC package may be positioned relative to the battery and/or the heater of a host device such that one or more OTP functional units is in thermal proximity to the battery and/or heater of the host device (and/or any other component whose temperature requires monitoring for safety reasons). For example, when a host device (e.g. an aerosol delivery system) is assembled, the ASIC package may be abutted against the battery such that changes in battery temperature are detectable by an OTP functional unit of the ASIC package. One or more thermal coupling elements (e.g. comprised of a thermal conductor such as copper or silver) may be disposed between a component whose temperature is to be monitored by the TM functional unit, and one or more OTP functional units of the ASIC package, forming a thermal coupling or bridge which enables changes in temperature of the component to be detected regardless of whether the ASIC package is positioned in thermal proximity to the component. In embodiments, an ASIC package of the present disclosure may be integrated into a combined battery and ASIC package, the combined ASIC and battery package comprising temperature sensing circuitry (e.g. one or more OTP functional units) integrated into the ASIC package which can directly detect changes in temperature of the battery due to thermal proximity of the temperature sensing circuitry and the battery, and transmit measurements of temperature to the TM functional unit.

A TM functional unit is provided with control logic configured to detect an over-temperature condition on the basis of temperature measurements (e.g. received from one or more OTP functional units), and provide an output to trigger a safety function on the basis of this determination. In embodiments, the control logic of the TM functional unit is configured to compare at least one temperature measurement (representative, for example, of a temperature of a battery or other power storage element of the host device, a temperature of a heater or heated region of the host device, and/or a temperature of the ASIC package itself) to a predefined threshold, and/or compare a function of at least one temperature measurement (for example a rate of change of temperature) to a predefined threshold. The predefined threshold may be a single value (e.g. where the TM functional unit is implemented in a non-configurable ASIC). Where the TM functional unit is implemented in a configurable ASIC, a plurality of thresholds may be mapped to different ‘enabled’ states which may be set for the TM functional unit, using approaches described herein for configuration of different parameters/parameter sets (represented, for example, by one or more matrices) mapped to different ‘enabled’ states. Where the TM functional unit is configured to monitor a plurality of temperatures (e.g. a temperature of a battery, and a temperature of a heater), the parameter set (e.g. matrix) mapped to each enabled state may comprise a separate threshold or set of thresholds associated with each of a plurality of component temperatures to be monitored by the TM functional unit. If the control logic determines a given temperature value is less than a respective predefined threshold, the OTP functional unit triggers a safety function. For example, the OVP functional unit may transmit a signal to a PMC, PMIC, and or dual switch (dual-SW) functional unit, to trigger a safety function, such as one of the actions described herein in relation to the OCP functional unit. The TM functional unit may comprise control logic configured to apply a plurality of thresholds to a discrete temperature or function of temperature (e.g. a temperature associated with a battery of the host device), and trigger other functional units (e.g. the PMIC functional unit) to modulate a rate of charging of the battery in dependence on battery temperature. It will be appreciated a TM functional unit may also apply under-temperature protection, particularly in respect of a monitored temperature associated with a battery of the host device, where a temperature is compared to a threshold, and if the temperature is below the threshold, one of the safety functions described herein is triggered.

The OTP functional unit may trigger a reset or clearing of one of the above safety functions if a subsequent temperature value is determined to be below the predefined threshold (in the case of over-temperature protection) or above the predefined threshold (in the case of under-temperature protection). Over- and under-temperature protection may be simultaneously provided by the TM functional unit in respect of any temperature being monitored as described herein.

### Short-Circuit Protection (SP) Functional Unit

In embodiments of the present disclosure, an ASIC package may be provided with a short-circuit protection (SP) functional unit. The SP functional unit may be directly or indirectly interconnected with any other functional unit of the ASIC package, to receive inputs from and provide outputs to other functional units such as the PCM and PMIC functional units described herein, providing tight integration of inter-related functionality within the ASIC package. An SP functional unit receives values indicative of, or directly determines the presence of, a short circuit on a current path within the host device, or within the ASIC package itself. The SP functional unit may comprise an ADC for conversion of a voltage applied across terminals of the ASIC package, or nodes within the ASIC package, or receive digital signals representing one or more voltage values from an ADC functional unit as described herein, and/or comprise an ADC for conversion of a current on a path external to the ASIC package, or between nodes within the ASIC package, or receive digital signals representing one or more current values from an ADC functional unit as described herein. Voltage and/or current values may be used to determine the presence of a short circuit on a current path within the host device, or the ASIC package itself, for example on a path used to supply current from a battery to a load (such as a heater) and/or a path used to supply current from a charging device to a battery, and/or a current path within the ASIC package itself. Voltage and current values associated with a current path within the host device and/or within the ASIC package, and received by or directly measured by the SP functional unit, may be used to determine a resistance of the current path.

An SP functional unit is provided with control logic configured to detect a short circuit condition on at least one current path, and provide an output to trigger a safety function on the basis of this determination. In embodiments, the control logic of the SP functional unit is configured to compare a resistance of at least one current path (e.g. a current path for suppling power to a load such as a heater) to a predefined threshold, and/or compare a function of at least one resistance measurement to a predefined threshold. The predefined threshold may be a single value (e.g. where the SP functional unit is implemented in a non-configurable ASIC). Where the SP functional unit is implemented in a configurable ASIC, a plurality of thresholds may be mapped to different ‘enabled’ states which may be set for the SP functional unit, using approaches described herein for configuration of different parameters/parameter sets (for example, in the form of one or more matrices) mapped to different ‘enabled’ states. If the control logic determines a resistance value is less than a predefined threshold, the SP functional unit triggers a safety function. For example, the SP functional unit may transmit a signal to a PMC, PMIC, and or dual switch (dual-SW) functional units, to trigger a safety function, such as one of the actions described herein in relation to the OCP functional unit.

The SP functional unit may trigger a reset or clearing of one of the above safety functions if a subsequent resistance value is determined to be above the predefined threshold.

### Power-Dissipation Timing (PDT) Functional Unit

In embodiments of the present disclosure, an ASIC package may be provided with a power-dissipation timing (PDT) functional unit (which in an aerosol delivery system context may be referred to as a puff timing or heating timing functional unit). The PDT functional unit may be directly or indirectly interconnected with any other functional unit of the ASIC package, to receive inputs from and provide outputs to other functional units such as the PCM and PMIC functional units described herein, providing tight integration of inter-related functionality within the ASIC package. A PDT functional unit comprises a clock/timer configured to determine elapsed duration from a trigger condition. The PDT functional unit may receive inputs from any functional unit associated with the triggering of power to a load of the host device (such as a PC functional unit as described further herein). For example, in embodiments where the host device is an aerosol delivery system comprising a heater, and the ASIC package comprises a heater-control functional unit controlling provision of heating signals to the heater (a PC functional unit), interconnection between the heater-control functional unit and the PDT functional unit is provided, and the heater-control functional unit is configured to transmit a trigger signal to the PDT functional unit when a heating cycle is initiated.

When the PDT functional unit determines that a functional unit associated with the triggering of power to a load of the host device (for example, a PC functional unit as described herein) has initiated a power cycle (e.g. a supply of heating current to a heater for generating aerosol), the PDT functional unit triggers a clock/timer to begin counting elapsed time. The counting may be maintained for as long as the PDT functional unit determines a discrete power cycle is ongoing (e.g. based on receiving signals from the functional unit associated with the triggering of power to a load, or based on directly monitoring electrical parameters on a current path used to provide power to the load). The control logic is configured to compare the elapsed time value to a threshold (for example, defined as a number of seconds, such as 3, 4, 5, 6, 7, 8, 9, or 10, seconds), and trigger a safety function if the threshold is exceeded. For example, the PDT functional unit may transmit a signal to a PMC, PMIC, and or dual switch (dual-SW) functional units, to trigger a safety function, such as one of the actions described herein in relation to the OCP functional unit.

When the PDT functional unit determines the PC functional unit has ended the power cycle (e.g. a heating cycle in the context of an aerosol delivery system), and/or a safety function triggered by elapsed time of a power cycle exceeding a threshold has been implemented (e.g. via feedback from a PMIC, PMC, and/or Dual-SW functional unit), the PDT functional unit may reset the elapsed time to zero. The PDT functional unit may reset the elapsed time to zero each time it determines based on signalling from the PM functional unit that a power cycle (e.g. representative of a heating cycle during a puff in an aerosol delivery device context), has been initiated.

### Dual Switch (Dual-SW) Functional Unit

In embodiments of the present disclosure, an ASIC package may be provided with a dual switch (dual-DW) functional unit, configured to provide redundant/failsafe switching functionality to the ASIC package. One or more dual-SW functional units may be directly or indirectly interconnected with any other functional unit of the ASIC package, to receive inputs from and provide outputs to other functional units such as the PCM and PMIC functional units described herein, providing tight integration of inter-related functionality within the ASIC package. A dual-SW functional unit is configured to implement a safety function triggered by any of the safety-related functional units described herein.

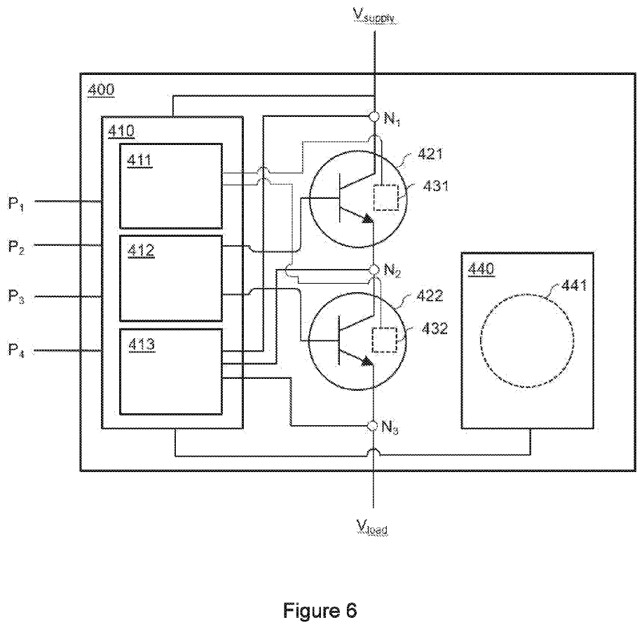

A dual-SW functional unit may be configured according to approaches for provision of a power controller package/power control unit/power supply unit as described in relation to FIG. 6 and the ‘switching safety’ section herein. It will be appreciated that in embodiments of the present disclosure, any of the hardware and associated functionality described in relation to FIG. 6 and the ‘switching safety’ section herein may be integrated into a configurable or non-configurable ASIC in the form of a dual-SW functional unit.

In the present disclosure, a determination by control logic of a safety-related functional unit leading to triggering of a safety function may be referred to as a determination of a ‘fault state’. A dual-SW functional unit may be configured according to the approaches set out in the ‘switching safety’ section herein, comprising at least a plurality of solid-state switches/FETs is distributed in series between a power supply terminal (V_{supply}), configured to be connected directly or indirectly to a power source, and a load terminal (V_{load}), configured to be connected directly or indirectly to a load. It will be appreciated that the power supply terminal and load terminal may be physical terminals of the ASIC package, or may be nodes defined on any current path to be switched by the dual-SW functional unit. Further to the plurality of solid-state switches, a Dual-SW functional unit may comprise all the components shown in FIG. 6 and described in the associated description (e.g. temperature control unit 411, FET control unit 412, electrical measurement unit 413, temperature sensors 431/432, electrical measurement nodes N1/N2/N3, and airflow sensor 440) or a subset of such components. Typically, a subset of components comprises at least a FET control unit 412 as described further herein, configured to switch the states of the solid-state switches by supplying a control voltage (i.e. VGS) to the respective gate of each switch based on signals received by the FET control unit 412 from one or more other functional units of the ASIC package (and in particular, one or more safety-related functional units as described herein, such as, for example a PCM functional unit). Thus when the control logic implemented by any of the safety-related functional units described herein determines a fault state is present (for example, due to an over-current, over-voltage, under-voltage, over-temperature, under-temperature, short-circuit, power cycle timeout, over-power, or other fault condition being determined by a functional unit such as, for example, one of the OCP, OVP, ULVP, OTP, SP, PDT, PMC, PMIC, TM, OTP functional units described herein), said functional unit is configured to directly or indirectly transmit a trigger signal to one or more dual-SW functional units of the ASIC package. Safety-related functional units may be configured to transmit such a trigger signal to the PMIC and/or PCM functional unit, which in such an architecture is configured to determine which of one or more dual-SW functional units to trigger to an open-circuit state, and to transmit trigger signalling to the FET control unit of one or more dual-SW functional units to cause the one or more dual-SW functional units to transition to an open-circuit condition by opening one or more solid-state switches as described further in the ‘safety switching’ section herein. The specific ones of one or more dual-SW functional units to trigger may be selected in dependence on the specific one or more safety-related functional units responsible for determining the fault state. In general terms, fault states related to the condition and/or discharge of a battery (e.g.

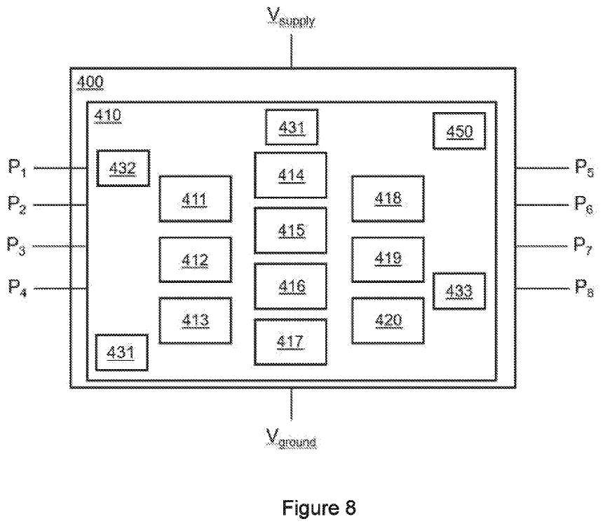

a battery over- or under-temperature condition, a battery under- or over-voltage condition, a battery over-power condition) may be used to trigger a dual-SW functional unit to prevent supply of power from the battery to circuitry of the ASIC package; fault states related to battery charging (e.g. a battery over- or under-temperature condition, a charging under- or over-voltage condition, a charging over-power condition, an incorrect charging polarity, a battery ultra-low voltage condition) may be used to trigger a dual-SW functional unit to prevent supply of power from a charger to the battery; fault states related to powering of a load (e.g. a short circuit condition on the load circuit, an under- or over-resistance condition of the load or a reference/shunt resistor associated with the load circuit, a load over-temperature condition) may be used to trigger a dual-SW functional unit to prevent supply of power from the battery to the load. A plurality of dual-SW functional units may be positioned on current paths at suitable locations in the ASIC package to prevent supply of power to and from different components of the host device and/or the ASIC package, as set out in respect of the example ASIC package of FIG. 8 herein.

For example, a dual-SW functional unit may be positioned such that the V_{supply} terminal is connected to a terminal of the ASIC package configured to receive current from a charging device (where the ASIC package is configured for use in a rechargeable host device), and all other circuitry of the ASIC package configured to receive current from the charging device is connected to the V_{load} terminal, such that charging current can only pass to other circuitry of the ASIC package having passed through the dual-SW functional unit (via the plurality of solid-state switches). In this manner, opening of one or both switches of the dual-SW functional unit can be used to isolate the circuitry of the ASIC package from charging current when a safety-related fault is determined to have occurred, which may improve the reliability and safety of the ASIC package, and a device in which the ASIC package is implemented.

A dual-SW functional unit may be positioned such that the V_{supply} terminal is connected to a terminal of the ASIC package configured to receive current from a battery, and all other circuitry of the ASIC package configured to receive current from the battery is connected to the V_{load} terminal, such that battery current can only pass to other circuitry of the ASIC package having passed through the dual-SW functional unit (via the plurality of solid-state switches). In this manner, opening of one or both switches of the dual-SW functional unit can be used to isolate the circuitry of the ASIC package from battery current when a safety-related fault is determined to have occurred, which may improve the reliability and safety of the ASIC package, and a device in which the ASIC package is implemented.

A dual-SW functional unit may be positioned such that the Vload terminal is connected to a terminal of the ASIC package configured to pass current from a PC functional unit or other power control functional unit to an external load (such as a heater) in the host device, and the V_{supply} terminal receives power from the PC functional unit used to drive the external load, such that current can only pass from the PC functional unit to the external load through the dual-SW functional unit (via the plurality of solid-state switches). In this manner, opening of one or both switches of the dual-SW functional unit can be used to prevent powering of the load, regardless of the operational state of the PC functional unit, when a safety-related fault is determined to have occurred, which may improve the reliability and safety of the ASIC package, and a device in which the ASIC package is implemented.

Optionally, any dual-SW functional unit integrated into the ASIC package may be provided with a temperature control unit 411, electrical measurement unit 413 and associated circuitry and functionality as shown in FIG. 6 described herein (such as, for example, optional temperature sensors and electrical measurement nodes associated with one or more solid-state switches of the dual-SW functional unit), the optional electrical measurement unit being configured to carry out monitoring/checks of whether each of the plurality of the switches is in an adverse operating state (e.g. a failure state), and optional control logic being configured to determine on the basis of this monitoring if at least one first switch (e.g. FET/MOSFET) of the plurality of solid-state switches is in an adverse operating state, and to modify an aspect of the provision of electrical current between the power supply and load terminals (i.e. V_{supply} and Vload) on the basis of said determination. This may provide greater reliability to switching used to implement safety functions when fault states as detected by safety-related functional units of an ASIC package.

In embodiments, one or more dual-SW functional units are directly integrated into one or more of the safety-related functional units described herein. For example, any safety-related functional unit described herein may comprise two or more solid-state switches connected to a FET control unit configured to independently switch each of the two or more solid-state switches as described herein, in response to a trigger from the functional unit into which the dual-SW functional unit is integrated. It will be appreciated any portion of any current path within the ASIC package may be provided with a dual-SW functional unit to enable fail-safe switching of the current path in the event of a fault state being determined by the ASIC package.

### Power Management Integrated Circuit (PMIC) Functional Unit

In embodiments of the present disclosure, an ASIC package may be provided with a charging functional unit, as described herein. In embodiments, this charging functional unit may be implemented as a power-management integrated circuit (PMIC) functional unit, and it will be understood the terms charging functional unit and PMIC functional unit may be used interchangeably herein. A PMIC functional unit may be directly or indirectly interconnected with any other functional unit of the ASIC package, to receive inputs from and provide outputs to other functional units, such as the PCM functional unit described herein, providing tight integration of inter-related functionality within the ASIC package. A PMIC functional unit determines or receives values indicative of a voltage associated with a battery or other power supply element which are indicative of the state of charge (e.g. the terminal voltage of a battery). The PMIC functional unit may comprise an ADC for conversion of a voltage applied across terminals of the ASIC package, or across nodes within the ASIC package, or receive digital signals representing one or more voltage values from an ADC functional unit or other functional unit as described herein.

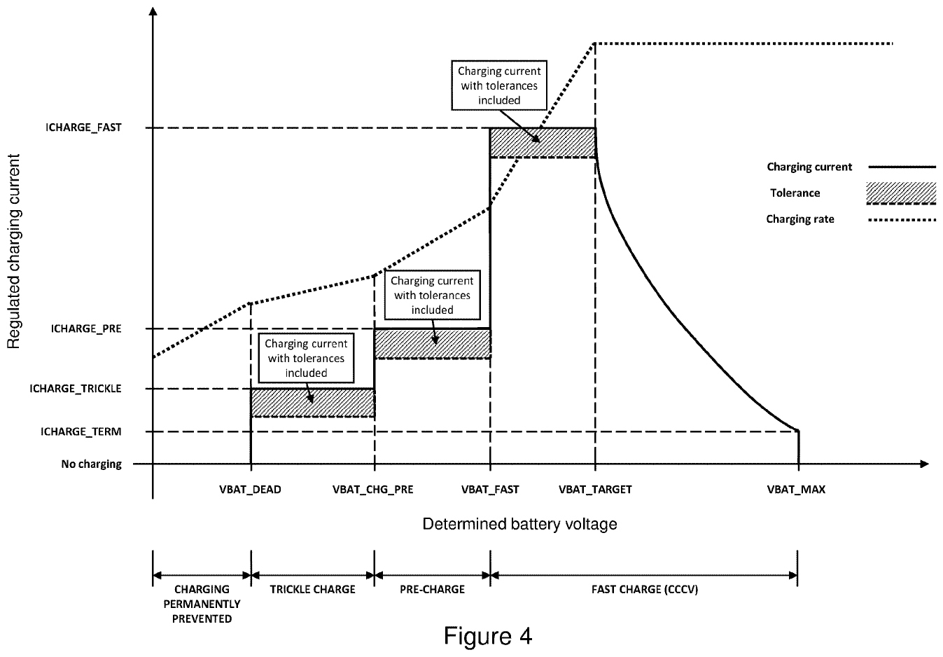

A PMIC functional unit is provided with control logic configured to control charging of a battery or other power supply element of the device by controlling power regulation circuitry of the PMIC to modulate the power supplied from a charger to the battery or other power supply element (these terms are used interchangeably herein), based on at least one control parameter. Thus in embodiments, the PMIC functional unit may be configured to determine a voltage associated with the battery (e.g. a terminal voltage), and to regulate the current supplied to the battery from a charger (e.g. an external charging unit connected to the host device via a wired or wireless connection) to target a predefined current level or range to be supplied to the battery, where the predefined level or range is selected in dependence on the determined battery voltage. The PMIC functional unit may access at least one matrix of values wherein battery voltage values or ranges of voltage value are mapped to single charging current values, or a range of charging current values, where the charging current is a regulated current to be applied through the terminals of the battery. Where the PMIC functional unit is implemented in a configurable ASIC, a plurality of matrices may be mapped to different ‘enabled’ states which may be set for the PMIC functional unit, using approaches described herein for configuration of different parameters/parameter sets mapped to different ‘enabled’ states. FIG. 4 shows an example of a charging scheme implemented in control logic of a PMIC functional unit, where the charging current is regulated based on determined battery voltage. The battery voltage, determined directly or indirectly by the PMIC functional unit as set out above, is compared to a set of thresholds represented, for example, in a matrix. In the example of FIG. 4, the thresholds of voltage are represented along the X axis, in increasing magnitude, as VBAT_DEAD, VBAT_CHG_PRE, VBAT FAST, and VBAT TARGET. The determined voltage, which may be measured periodically, for example according to a clock speed of a processing core of the ASIC package (ASIC core), is compared to the thresholds of voltage set out above, and power regulation circuitry of the PMIC functional unit is controlled to regulate an input charging signal (e.g. received from a charger via terminals of the ASIC package) to provide a regulated charging current to be output to the battery (e.g. to be output via terminals of the ASIC package). The current of the regulated charging output to the battery, shown on the Y axis, is controlled based on the thresholds of voltage between which the battery voltage is determined to fall. Thus, as shown in the example of FIG. 4, the control logic may determine that where the battery voltage is below VBAT_DEAD, no charging current should be provided (and charging is thus permanently prevented); where the battery voltage is between VBAT_DEAD and VBAT_CHG_PRE, a maximum charging current of ICHARGE_TRICKLE should be supplied to the battery (to provide trickle charging); where the battery voltage is between VBAT_CHG_PRE and VBAT_FAST, a maximum charging current of ICHARGE_PRE should be supplied to the battery (to provide pre-charging); where the battery voltage is between VBAT_FAST and VBAT_TARGET, a maximum charging current of ICHARGE_FAST should be supplied to the battery (to provide fast charging); and where the battery voltage is above VBAT_TARGET, either no further charging current should be provided, or the charging current should be attenuated down to zero in dependence on where the battery voltage sits in the range between VBAT_TARGET and VBAT_MAX (as shown in FIG. 4, where above VBAT_TARGET, the charging current is reduced from ICHARGE_FAST to ICHARGE_TERM according to non-linear function, before charging is halted at a VBAT_MAX). As shown in the example of FIG. 4, the current to be applied based on the determined voltage may not be a single value, but may be controlled by the PMIC functional unit to be within or allowed to fall within a range (e.g. defined by a maximum value and an allowable tolerance below the maximum value), where the range is typically determined by the characteristics of the power regulation circuitry of the PMIC functional unit. FIG. 4 shows how modulating the charging current in dependence on battery voltage, using a plurality of thresholds of battery voltage, allows the charging rate to be modulated. This may provide more efficient charging, tailored more specifically to the characteristics of the battery or other power supply element to be charged, while increasing safety by avoiding over-current conditions at states of low battery voltage. It will be appreciated the actual thresholds of voltage and their mapping to charging current values or ranges will be dependent on the characteristics of one or more battery types the charging of which is to be supported by the PMIC functional unit (e.g. via a different ‘enabled’ mode of the PMIC functional unit per battery type, when the PMIC functional unit is implemented in a configurable ASIC package).

In embodiments, the PMIC functional unit may be configured to regulate charging voltage to be applied for charging a battery or other power supply element in a similar manner to that described above and illustrated in FIG. 4. Thus, the control logic may be configured to determine a voltage associated with the battery (e.g. a terminal voltage), and to regulate the voltage of a charging signal to target a predefined level or range, where the predefined level or range is selected in dependence on the determined battery voltage. As in the example of regulating charging current based on battery voltage, the PMIC functional unit may use at least one matrix of values wherein battery voltage values or ranges of voltage values are mapped to single charging voltage values, or a range of charging voltage values, where the charging voltage is a regulated voltage to be applied to the terminals of the battery to provide charging. Where the PMIC functional unit is implemented in a configurable ASIC, a plurality of matrices may be mapped to different ‘enabled’ states which may be set for the PMIC functional unit, using approaches described herein for configuration of different parameters/parameter sets mapped to different ‘enabled’ states. For example, different ‘enabled’ states may be provided for different battery types/capacities, defining different mappings of battery voltage to charging current and/or charging voltage which are appropriate for each specific battery type/capacity.

### Power Controller (PC) Functional Unit

In embodiments of the present disclosure, an ASIC package may be provided with a power controller (PC) functional unit configured to regulate power supplied from a battery or other power supply element to a load (e.g. a heater in a context where the host device is an aerosol delivery system). A PC functional unit may be directly or indirectly interconnected with any other functional unit of the ASIC package, to receive inputs from and provide outputs to other functional units, such as the PCM functional unit described herein, providing tight integration of inter-related functionality within the ASIC package. The functionality described herein for a PC functional unit may be implemented by control logic of a dedicated PC functional unit, or implemented as part of the control logic of a PMIC functional unit as described herein, such that a PMIC functional unit provides control over both charging of a battery (or other power supply element), and discharge from the battery to one or more loads (e.g. a heater). A PC functional unit may be implemented using the circuitry of a power control unit as shown in FIG. 4, and described in the ‘safety switching’ section herein.

A PC functional unit is directly or indirectly connected to the battery, and to one or more loads (e.g. a heater) of the host device via the terminals of the ASIC package, and comprises one or more switches configured to regulate the supply of power to the load from the battery. Power regulation circuitry of the PC functional unit comprises one or more switches (e.g. MOSFET switches) to turn a supply of current from the battery to at least one load on and off, and may comprise further circuitry configured to regulate the current and/or voltage supplied to the at least one load (e.g. the PC functional unit may implement DC/DC or boost conversion of the battery output). The power regulation circuitry may comprise a dual-SW functional unit as described herein, integrated into the PC functional unit. Alternatively or additionally, the PC functional unit may comprise SMPS (switched mode power supply) circuitry implementing pulse width/frequency modulation techniques (e.g. PWM), to regulate power to the at least one load. The PC functional unit is configured to initiate a supply of power to one or more loads of the host device in response to a first trigger signal, for example a signal directly or indirectly received from a user input device such as a button or airflow sensor of the host device, or from a sensor (for example an airflow sensor, such as a MEMS pressure sensor or microphone) integrated into the ASIC package. An airflow sensor may be integrated into the PC functional unit as shown in FIG. 6, and further described in the ‘safety switching’ section herein. The PC functional unit is further configured to end a supply of power (e.g. a power cycle) to the one or more loads of the host device when an end condition is satisfied (e.g. a second trigger signal directly or indirectly received from a user input device such as a button or airflow sensor of the host device, and/or an airflow sensor integrated into the ASIC package, and/or elapsing of a predefined time since the first trigger signal was received).

In embodiments, the control logic of the PC functional unit may be configured to provide constant output power to a load (such as a heater of an aerosol delivery system in which the ASIC package is incorporated), and to cease the provision of power once the target power cannot be attained due to depletion of battery charge. Alternatively the control logic of the PC functional unit may be configured to vary output power to a load comprising a heater, based on a feedback of temperature from the heater (e.g. using resistance measurements where the heater comprises a material with a non-constant temperature coefficient of resistance). Where the PC functional unit is configured to target constant power, the control logic may be configured to determine a state of charge (SoC) of the battery or other power supply element, and vary the target power output to the at least one load based on a parameter set (e.g. implemented as at least one matrix) which maps a plurality of ranges of determined state of charge of the battery to a plurality of values or ranges of target output power. The SoC may be determined based on battery terminal voltage using approaches described herein (e.g. in relation to the PMIC functional unit), and the PC functional unit, if implemented separately to a PMIC functional unit, may determine battery voltage as described herein in relation to the PMIC. In embodiments, a value representing battery voltage is directly used to represent the SoC, or SoC may be defined by an equation such as the following:

$$( \frac{VBAT\_ACTUAL - VBAT\_DEAD}{BAT\_MAX - VBAT\_DEAD} ) \times 100 \%$$

where the VBAT_ACTUAL is the present battery voltage, VBAT_DEAD is the battery voltage at which the battery is determined to be fully discharged, and VBAT_MAX is the nominal or actual maximum battery voltage when fully charged.

The PC functional unit may modulate the power output to at least one load (e.g. a heater of a host device comprising an aerosol delivery system) via a mapping of a plurality of target output power values to a plurality of ranges of SoC, which may be indicated by, for example, a matrix which can be accessed by the PC functional unit according to approaches described herein.

In one example, where the host device comprises a heater, the following mapping of SoC range to target output power for a load comprising a heater of an aerosol delivery system may be implemented:
if SoC is between 100%-60%, the power output is set at 6.5 W.
if the SoC level is between 100%-60%, the power output is set at 6.3 W.
if the SoC level is between 59%-20, the power output is set at 6.1 W.
if the SoC level is between 59%-20%, the power output is set at 5.9 W

The power output may be regulated to achieve the target output power by, for example DC/DC conversion and/or PWM techniques.

Further criteria may be applied by the PC functional unit as part of a power modulation scheme. Thus, for example, the resistance of the load may be determined (e.g. via voltage and current measurements on the load path as described herein) and if this is outside of a predefined range, a fault condition may be determined which is used to trigger a safety function (e.g. the opening of one or more switches on a load current path by a Dual-SW functional module).

### Protection Circuit Module (PCM) Functional Unit

In embodiments of the present disclosure, an ASIC package may be provided with a protection circuit module (PCM) functional unit, configured to protect a battery or other power supply element from input or output power which is outside of predetermined allowable characteristics, in terms of, for example, the instantaneous charging or discharging power, and/or a rate of change of charging or discharging power. A PCM functional unit may be directly or indirectly interconnected with any other functional unit of the ASIC package, to receive inputs from and provide outputs to other functional units, such as the PCM functional unit described herein, providing tight integration of inter-related functionality within the ASIC package. In embodiments, the functionality described herein as associated with a PMC functional unit may be integrated into a PMIC functional unit as described herein, or may be implemented as a separate functional unit with appropriate interconnections with the PMIC functional unit to allow input and output signals to be transmitted between the PMC and PMIC functional units.

A PMC functional unit is provided with control logic configured to determine a charging or discharging power associated with a battery or other power supply element of the host device. This determination may be carried out by receiving signals from one or more other functional units, such as a PMIC functional unit, and/or ADC functional units configured to determine current and voltage values associated with charging and discharge current paths of the battery. Alternatively or additionally the PMC functional unit may be directly connected to the battery via terminals of the ASIC package, and comprise ADC circuitry to directly determine voltage and current values associated with charging and discharge current paths of the battery. The control logic of the PMC functional unit is configured to determine instantaneous charging and/or discharging power, and/or rate of change of said power. One or both of the instantaneous power and rate of change of power for each of battery charging and battery discharge may be compared to predefined thresholds, determined based on the characteristics of the battery and other circuitry/components of the device (e.g. the maximum power rating of a charging device, a heater of the device, the ASIC package itself, etc). The PMC functional unit may be additionally configured to determine the polarity of a charging current associated with the battery (e.g. via current measurements as described herein), and compare this polarity to a predefined allowable polarity.

Where a determined power of charge or discharge of the battery (whether instantaneous or a rate of change) is determined by the control logic to be above a predefined threshold, and/or the charging current is determined to have incorrect polarity, the control logic of the PMC functional unit may be configured to trigger a safety function, such as, for example, the triggering of a dual-SW functional unit to open one or more switches (e.g. MOSFET switches) on current paths between a charging device and the battery if the determined power exceeding the threshold relates to charging), and/or between the battery and one or more loads (e.g. a heater, one or more functional units of the ASIC package itself, etc) if the determined power exceeding the threshold relates to discharge of power to one or more loads. The implementation of this safety switching functionality may be carried out in accordance with approaches set out in the ‘switching safety’ section herein.

The PCM functional unit may provide a centralised power control function by receiving safety function trigger signals output by other safety-related functional units, and outputting trigger signals to one or more dual-SW functional units of the ASIC package in response. The specific ones of one or more dual-SW functional units triggered by a PCM functional unit to switch to an open-circuit state may be determined by control logic of the PCM functional unit on the basis of one or both of (i) the specific safety-related functional unit(s) transmitting the safety function trigger signal, and/or (ii) a type of safety function trigger signal received by the PCM functional unit.

It will be appreciated that PCM functionality described herein may be integrated into a PCIM functional unit, and thus where functions are described as being carried out by a PCM functional unit, this may in embodiments either be carried out by a standalone PCM functional unit, or by a PCIM functional unit integrating PCM functionality as described herein.

### Inter-IC Bus (I2C) Functional Unit

In embodiments of the present disclosure, an ASIC package may be provided with an inter-IC bus (I2C) functional unit, configured to support communication between functional units of the ASIC package, and external components of the host device comprising circuitry, such as sensors. An I2C functional unit may be directly or indirectly interconnected with any other functional unit of the ASIC package, to receive inputs from and provide outputs to other functional units, such as the PCM functional unit described herein, providing tight integration of inter-related functionality within the ASIC package. An I2C functional unit, where included, is directly or indirectly connected to one or more terminals of the ASIC package, to allow electrical connection between external components and the I2C functional unit via the terminal(s) of the ASIC package. For example, an external component may comprise, by way of non-limiting examples, a further ASIC package, further controller of the host device (e.g. MCU or FGPA chip), accelerometer, gyroscope, microphone, airflow sensor, wireless module (such as a Bluetooth™ or Bluetooth Low Energy™ module), location services module (such as a GPS positioning module), electrical sensing circuitry (e.g. an ammeter circuit or voltmeter circuit), display module (comprising one or more LEDs, or a pixilated display unit), haptic feedback module (e.g. an eccentric rotating mass module), and/or a user input mechanism (e.g. one or more buttons, touch sensors, touchscreen display modules). The I2C functional unit may carry out input and/or output signal conversion, according to known approaches for provision of inter-integrated-circuit bus channels, and interconnect to other functional modules of the ASIC package (e.g. a processing core). The I2C functional unit may accordingly receive output from functional units of the ASIC package and transmit these via relevant terminals to control external components (e.g. to control external components to provide feedback based on outputs of control logic implemented by functional units of the ASIC package), and/or receive input from external components (e.g. measurements from sensors, and inputs from user input devices) and route these to functional units which perform operations based on such input.

In embodiments, the functionality described herein as associated with a I2C functional unit may be integrated into a processing core of the ASIC package, or may be implemented as a separate functional unit with appropriate interconnections with the processing core and/or any other functional unit of the ASIC package, to allow input and output signals to be transmitted between the I2C functional unit and other functional units of the ASIC package.

Where a configurable ASIC comprises one or more I2C functional units as described herein, the setting of a target configuration for the ASIC package may comprise enabling the I2C functional unit(s) only if external sensors/input devices, or external feedback devices, are comprised in the host device in which the ASIC package is to be implemented. Thus, where 12C functionality is not required, because there are no components in the host device requiring I2C support (for example, in applications where all sensors and feedback devices are integrated into the ASIC package), the ASIC package may be configured to disable the I2C functional unit(s), where provided.

### Safety Switching

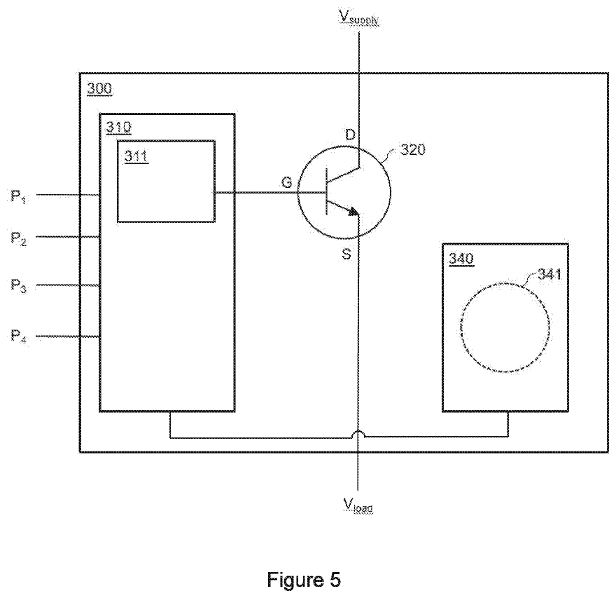

In embodiments of the present disclosure, an ASIC package may be provided with switching circuitry (alternatively referred to herein as ‘safety switching’ circuitry), which can open and close the circuit path between the power source and the load. In an aerosol provision system context such as shown schematically in FIG. 1 and described in the accompanying text, the load may comprise an aerosol generator 48 such as a resistive heating element, but it will be appreciated the load could in principle be associated with any functionality associated with the aerosol provision system (or another device in which a power control unit according to the present disclosure is comprised, as described further herein), and the specific functionality to be supported is not of particular significance to the principles of fabrication and operation of a power control unit as described herein. Aspects of the present disclosure are particularly directed to embodiments in which a power control unit comprises one or more solid-state switches, and thus embodiments of the power control units described herein may be particularly applied in contexts involving supply of power from a power supply to a load using solid-state switches (including in contexts outside of the field of aerosol provision systems). Solid-state switches (also known as ‘relays’) typically provide a gate of variable resistance between a collector/drain terminal (connected to supply voltage) and an emitter/source terminal (connected to a load), wherein the resistance of the gate varies in dependence on a voltage applied to a base/gate terminal. These terminal designations may be used interchangeably herein. Typically, solid-state switches are implemented as field-effect transistors (FETs), of which there exist a range of sub-types, including the metal-oxide-semiconductor field-effect transistor (MOSFET), junction field-effect transistor (JFET), and metal-semiconductor field-effect transistor (MESFET). Approaches as described herein may be applied to power control units comprising these, and/or other FET types, including new types yet to be developed. A FET is typically characterised by low on/closed resistance and high off/open resistance on the drain-to-source electrical path, high gate-to-drain current resistance (thus isolating the control circuitry and the current path through the main gate between drain and source), and a low power-draw for switching control signals used to switch the gate state between open/off and closed/on, or vice-versa. FIG. 5 shows an exemplary implementation of a power control unit comprising a power controller package 300 (‘controller package’), comprising a single solid state switch/FET 320, control logic 310 comprising a FET control module/functional unit 311, and an airflow sensor 340 with a port 341 for fluid connection to a region of an aerosol provision system which is part of an airflow path in which a pressure drop is induced during user draw. In this example, the control logic 310, FET 320, and airflow sensor 340, are implemented in the same package 300, however this is merely exemplary, and these components may be separately provided (e.g. as part of separate assemblies, for example on discrete silicon substrates) which are provided with suitable electrical interconnects (e.g. wires or other conductive lines). The FET 320 comprises a switchable solid-state gate disposed between the drain/collector terminal (D) and the source/emitter terminal(S); and a gate/base terminal (G), at which the control logic 310 can apply a voltage e.g. (between terminal G, and terminal S or ground), to control the conductivity of the gate between terminals D and S. The drain terminal S is connected to supply voltage V_{supply} (e.g. being directly or indirectly connected to the battery of a device in which the power controller package 300 is implemented), and the source terminal S is connected to an electrical load (e.g. a heater or other aerosol generator, in an aerosol provision system context). The gate terminal G is connected to FET control unit 311 of control logic 310, the FET control unit 311 being configured to provide a variable voltage to terminal G to switch the FET gate between closed/on, and open/off states. As is known to the skilled person, the state of a FET in use is partly characterised by various electrical parameters, including I_{D} (current passing the gate), R_{DS} (resistance across terminals D and S), and Vos (voltage across terminals D and S). Typically, the operating characteristics of a solid-state switch/FET are as follows (the actual values of the various parameters being characterised, unless specified otherwise, by the particular design/model of FET and environmental factors). When the voltage applied to the gate terminal (i.e. V_{GS}) is below a threshold voltage (i.e. V_{TH}), the current between D and S (i.e. I_{D}) is low (i.e. at/towards the bottom end of the normal operating range), and the resistance between D and S (i.e. R_{DS}) is high (i.e. at/towards the top of the normal operating range), and the voltage across D and S (i.e. V_{DS}) is thus high (i.e. at/towards the top of the normal operating range). This regime, where V_{GS}<V_{TH}, may be referred to as operation in ‘cutoff mode’. In the regime where V_{TH}<V_{GS}<V_{SAT} (where V_{SAT} is the ‘saturation voltage’), I_{D}, R_{DS}, and V_{DS}, will typically vary with varying V_{GS}. Typically, in this regime, which may typically be referred to as ‘linear mode’, R_{DS} may typically vary linearly or quasi-linearly with varying V_{GS}, with according variation in I_{D} and V_{DS}. In the regime where V_{GS}>V_{SAT}, R_{DS} substantially ceases to vary as V_{GS} continues to increase above V_{SAT}. This regime may typically be referred to as ‘saturation mode’. Thus the current flow across the gate (i.e. I_{D}) and the power supplied to the load (e.g. a heater) tend to their maximum values in saturation mode. Thus, in an exemplary use case, the control logic 310 is operable to control the power delivered to the load from the power supply/battery by varying the voltage supplied to the gate (G), in dependence on signals received at the control logic 310 from an airflow sensor 340. It will be appreciated that in other examples, the power controller package 300 may not comprise an airflow sensor 340, and signals to indicate the desired switching state may be provided to the control logic 310 by a different activation element, such as a manual user input element (e.g. a button), or a further controller (e.g. an MCU or ASIC), which may be integrated into the power control package 300, or connected via one or more input pins (e.g. a bus) associated with the power control package 300. Four exemplary input pins P1, P2, P3, and P4, are shown in FIG. 5, but it will be appreciated the number of pins may be selected by the skilled person dependent on particular requirements of a specific use case. Where an airflow sensor 340 is used, this may comprise, for example, a MEMS sensor (such as a MEMS pressure sensor), comprising a port 341 to expose a pressure-sensitive element to a pressure drop induced in an aerosol provision system when a user puffs on the device. Depending on the pressure sensor design, a further port (not shown) may expose the pressure sensitive element to a reference pressure (e.g. ambient pressure). The control logic 310 is configured to receive signals from the sensor/manual user input element, or a further controller, and output a switch control voltage (Vos) to the FET gate terminal (G) to control the gate state. Thus, in some embodiments, the airflow sensor 340 outputs to the control logic 310 a signal which is proportional to a pressure drop sensed at the port 341. The FET control unit/functional unit 311 (which may be implemented in software, where the controller is an MCU, or may comprise a functional unit/module of an ASIC), is operable to provide a switch-control voltage to the FET gate terminal (G), the amplitude of which varies in dependence on the input signal received from the activation element. Thus when the control logic 311 determines the input signal has exceeded a trigger condition (e.g. a threshold), it may provide a continuous or pulsed (e.g. square wave) control signal Ves, of a magnitude greater than V_{TH}. For example, pulsed signal at peak amplitude of V_{GS}=V_{SAT} or V_{GS}>V_{SAT} may be used, with the duty cycle and/or periodicity of the pulsed signal being controlled to vary the power supplied to the load between OW and the peak power determined by the supply voltage, maximum supply current, and the losses in the circuit path. This approach may be used to implement a pulse-width modulation scheme for power supply to the load, using approaches known to the skilled person.

It will be appreciated the above examples of operation of the configuration of FIG. 5 are only for context, and the principles herein are applicable to a power control unit/package 300 comprising at least one solid-state switch, regardless of the specific way the switch is controlled in normal operation to supply power to the load (e.g. whether or not an actuation element such as an airflow sensor 340 is included).

Solid-state switches (such as FET 320 shown in the exemplary power control unit of FIG. 5) may degrade and fail due to a variety of mechanisms, which may be due to dynamic loading above various safe limits of current, voltage, and/or total power dissipation, or due to environmental impacts (e.g. damage due to external factors). As a non-exhaustive set of examples of dynamic-loading failure modes, and without wishing to be bound by any particular physical theory, it is thought that a maximum operating voltage of the FET may be exceeded, leading to material disintegration/dielectric breakdown via short circuit; and/or a maximum rate of voltage rise may be exceeded (e.g. due to a rapid transient spike in voltage caused by, for example, electrical noise or RF interference), causing insulation between the gate and the body of the FET package to be degraded; and/or power dissipation may exceed a threshold rate, causing degradation of materials (e.g. de-soldering and/or de-bonding of components from a die). The latter may be caused by a maximum operating current being exceeded, for example by a short-circuit condition on the load. Dynamic loading in unsafe regimes may lead to rapid (e.g. near-instantaneous) failure, or may degrade the FET more slowly (e.g. over a plurality of switching cycles) such that it continues to function with impaired operational characteristics. Even if safe loading limits are not exceeded, degradation may still occur due to aging as the number of switching cycles increases cumulatively. Environmental impacts such as overheating, water ingress, contamination, and radiation damage, may also degrade materials comprised in the FET leading to failure, or pre-failure degradation.

A solid-state switch/FET, such as FET 320 of FIG. 5, may be in one of a plurality of different operating states, depending on a degree of degradation. These include a complete failure state, which may be categorised by the failure of the FET gate to respond to control signals from the control logic 310. For example, the FET may be in a complete failure state, where the gate resistance (i.e. R_{DS}) is high (e.g. at or above its nominal ‘open/off’ rating), and cannot be reduced by applying a control voltage (e.g. a control voltage at V_{TH}<V_{GS}<V_{SAT}, V_{GS}=V_{SAT}, or V_{DS}>V_{SAT}). This operating state may be referred to as an ‘open failure’. In other circumstances, a complete ‘closed failure’ operating state may be considered to have occurred where significant current (i.e. I_{D}) can pass the gate of the FET despite the control voltage (i.e. V_{GS}) being below the threshold voltage (i.e. V_{TH}). In some circumstances, the gate resistance (i.e. R_{DS}) in an open-failure state may be low (e.g. at or below its nominal ‘open/off’ rating) even when V_{GS} is substantially zero. A partial closed-failure state may occur where R_{DS} remains between the nominal values in the ‘on’ and ‘off’ states despite the control signal voltage V_{GS} being below the threshold V_{TH}. Complete or partial closed-circuit failures may be considered particularly dangerous failure states in operating contexts where the load comprises a heater, since the FET 320 cannot be switched to an open-circuit state by the controller 310 to turn off the supply of current and thus terminate heating. This may lead to overheating, causing damage to the device, and potentially injury to a user and/or risk of fire.

It is recognised that a FET may be in a degraded operational condition without being/prior to entering a complete failure state (e.g. open-or-closed circuit failure). A degraded operational condition may be defined as one in which physical degradation of the FET has caused the response behaviour (i.e. response to differing control voltage Ves) to vary appreciably from the nominal behaviour of the FET in the new/virgin/pristine/as-manufactured state. This variation may be characterised as a degradation-induced drift over time in at least one operating parameter of the FET. For example, the curve representing the relationship between control voltage (i.e. Ves) and resulting gate voltage (i.e. V_{GS}) for the same supply voltage at the drain terminal (D) may drift over time/use, as may the values of V_{TH} and/or V_{SAT}. Indeed, depending on the nature of the degradation, any of the defining operating characteristics/parameters of the FET (including scalar values, and rates of change of various orders) may drift as the FET ages, and may also be induced/accelerated by dynamic loading in regimes exceeding the rated operating limits (e.g. limits for V_{GS}, V_{DS}, and I_{D}) as defined by manufacture.

The inventor has recognised that in power control units comprising solid-state switches/FETs, and particularly those where the load under control comprises a heater (such as in many aerosol provision systems), strategies to mitigate the risk of complete FET failure and/or prevent complete failure of FETs and/or monitor FET degradation state are of interest.

Thus, according to embodiments of the present disclosure, there is provided a power control unit configured for use in an electrical/electronic device (such as an aerosol provision system), the power control unit comprising: at least one power supply terminal for connection to an electrical power supply; at least one load terminal for connection to an electrical load; an electrical current path configured to connect the at least one power supply terminal to the at least one load terminal; and a plurality of switches connected in series along the electrical current path, wherein the power control unit comprises control logic configured to independently switch each of the plurality of switches between an open-circuit state and a closed-circuit state; wherein the control logic is configured to supply electrical current to the load terminal via the electrical current path; and wherein the control logic may be further configured to determine if at least one first switch of the plurality of switches is in an adverse operating state, and to modify an aspect of the provision of electrical current to the load terminal via the electrical current path on the basis of said determination.

FIG. 6 shows a power control unit 400 according to embodiments of the present disclosure. As in the power control unit of FIG. 5, the power control unit 400 comprises control logic 410, and an optional airflow sensor 440, as described in association with FIG. 5. A plurality of solid-state switches/FETs is distributed in series between a power supply terminal (V_{supply}), configured to be connected directly or indirectly to a power source (e.g. a battery 26 as shown in FIG. 1) and a load terminal (V_{load}), configured to be connected directly or indirectly to a load (e.g. an aerosol generator such as a heater 48 as shown in FIG. 1). The control logic 410 comprises various functional modules/units. These are shown schematically in FIG. 6 as being spatially distinct, and whilst in some instances, the functionality of each functional unit may be provided by a different circuit module (e.g. series of cells and electrical interconnects implemented as part of an ASIC), in other instances, the functionality of one or more of the functional units (or all the functional units) may be provided by the same circuitry/hardware, with each functional unit supported virtually by different firmware/software routines (e.g. where the power control unit 410 comprises a microcontroller unit (MCU) implementing one or more routines defined in firmware/software). In other words, the reference to different ‘functional units’ of the power control unit 410 is intended herein to allow different functionalities of the power control unit 410 to be described, without necessarily implying each functional unit is implemented using discrete circuitry or software elements. The gate terminals (G) of each of the switches are independently connected to a FET control unit 412, configured to provide an AC/pulsed or DC driving voltage to the gate of each switch to toggle it between open and closed states (as described in accordance with FIG. 5). The standard driving voltage parameters in normal usage can be configured according to known approaches, taking into account the characteristics of the specific switches used (i.e. as defined by the manufacturer). Two solid-state switches (e.g. FETs) 421 and 422 are shown in the example of FIG. 6, but it will be appreciated that in other embodiments, any number of switches may be provided in series, with the number of measurement nodes and switch state sensors scaled accordingly, with an electrical measurement node defined between neighbouring pairs of switches, and with each switch connected to the FET control unit 412.

In any of the embodiments described herein, the power control unit 400 may comprise an application specific integrated circuit, ASIC, package, in which at least the control logic 410 is fabricated onto a single die/chip/wafer, or distributed among different dies/chips/wafers packaged into the same casing. Optionally, the plurality of switches with associated electrical measurement nodes and/or switch state sensors defined on one or more separate discrete elements (e.g. circuit boards) connected to the control logic 410 by appropriate electrical interconnects. In some embodiments, the switches are integrated with the control logic 410 on a single semiconductor die (e.g. a silicon die), and the controller package 400 may comprise a high power density ASIC power controller/SMPS. Where the controller package 400 comprises an ASIC, the functions described in the embodiments herein may be implemented using chip design and fabrication processes known to the skilled person. For example, the control logic (e.g. in terms of how switching control signals are provided in response to inputs, and how switch degradation monitoring approaches described herein are implemented) may be translated into a hardware description language (e.g. Verilog or VHDL), in a register-transfer level (RTL) design stage. There may typically follow a functional verification stage, where the control logic is simulated (e.g. via bench testing, formal verification, emulation, or creating and evaluating an equivalent pure software model). There may typically follow a logic synthesis stage where the RTL design is transposed/compiled into a set of standard or custom cells, typically derived from a standard-cell library of logic gates configured to perform specific functions, to form a gate-level netlist. In a placement stage, the gate-level netlist is processed to derive a placement of the cells on a die (e.g. a silicon die). During placement, the cell positioning is typically optimised for efficiency and robustness. In a routing stage, the netlist is typically used to design appropriate electrical connections between the standard cells, to provide the control logic. The output of the placement and routing stages is typically the derivation of the photo-mask(s) (‘masks’) which will be used to fabricate the circuitry of the ASIC package (e.g. the control logic 410) on the die material.

The manner in which the FET control unit 412 is configured to switch the states of the switched by supplying a control voltage (i.e. V_{GS}) to the respective gate of each switch is context-dependent, and may be based on an output signal received by the FET control unit 412 from an actuation element (e.g. a manual activation element such as a button, or one or more sensors), or may be based on internal signal flows/algorithms implemented by control logic 410 (e.g. so that switches are triggered on and off according to a predefined schedule). The power control unit 400 may comprise a wired or wireless data connection to one or more external computing devices, which output signals to terminals of the controller package 400 on the basis of which the FET control unit 412 is triggered to switch the states of the switches. Thus power control unit 410 may optionally comprise control logic (e.g. comprised in FET control unit 412) configured to detect a trigger signal provided by an actuation element, and to control the supply of electrical current from an external power supply connected to the power supply terminal (i.e. (V_{supply}), to the load terminal (i.e V_{load}), via the electrical current path passing through the plurality of switches on the basis of the trigger signal. In some embodiments, such an actuation element may be integrated into the power control unit 400, as shown in FIG. 6, where an airflow sensor 440, as described in accordance with FIG. 5, is integrated into the power control unit 400, which may comprise an ASIC package. In some embodiments, such an ASIC package may comprise an airflow sensor implemented as a MEMS pressure sensor or microphone, and the power control unit 400 may in these contexts be referred to as an aerosol provision system power control unit.

As described above, in embodiments of the present disclosure, the control logic 410 defined in the power control unit 410 is configured to determine if at least one first switch (e.g. FET) of the plurality of switches is in an adverse operating state, and to modify an aspect of the provision of electrical current between the power supply and load terminals (i.e. V_{supply} and V_{load}) on the basis of said determination. In some embodiments, the adverse operating state comprises a failure state, and the control logic 410 is configured to determine at least one first switch of the plurality of switches is in an adverse operating state by determining the at least one first switch has failed. The failure state may comprise a complete failure state, as described further herein. Thus, in some aspects of these embodiments, the power control unit 400 is configured to determine at least one first switch has failed non-reversibly in a closed-circuit state. In some aspects of these embodiments, the power control unit 400 is configured to determine the at least one first switch has failed non-reversibly in an open-circuit state.

FIG. 3 shows schematically three nodes N1, N2, and N3, respectively positioned at locations prior to the two switches 431 and 422, between the two switches, and after the two switches, on the current path between power supply and load terminals. An electrical measurement unit 413 associated with the controller 410 is connected to each of the nodes N1, N2, and N3, to allow electrical parameters associated with the switches 421 and 422 to be determined. For example, the drain-to-source voltage (i.e. V_{DS}) of switch 421 can be measured across nodes N1 and N2, and the drain-to-source voltage (i.e. V_{DS}) of switch 422 can be measured across nodes N2 and N3. Optionally, the current (i.e. I_{D}) through the plurality of switches may be measured at a position between V_{supply} and V_{load}, via ammeter circuitry connected to the electrical measurement unit 413 (circuitry not shown in FIG. 6). By providing hardware or software interconnects between the FET control unit 412 and the electrical measurement unit 413, the gate to source voltage (i.e. Ves) for each switch can be determined by the electrical measurement unit 413. Typically, the electrical measurement unit 413 is configured to determine the supply voltage connected to the power supply terminal using approaches for power-supply output voltage measurement known to the skilled person. Other electrical parameters as described herein may be determined by the electrical measurement unit 413 using approaches known to the skilled person. What may be considered significant is that these parameters can be determined independently for each of the plurality of switches. The electrical measurement unit 413 and associated circuitry (e.g. connecting to nodes N1, N2, and N3) may be considered to comprise a separate switch status sensor associated with each one of the plurality of switches.

In some embodiments, the electrical measurement unit 413 may determine a failure state of a given first switch of the plurality of switches by measuring the drain to source voltage (i.e. V_{DS}) across the switch at appropriate measurement nodes, and determining if this is in the expected range based on a predefined control voltage (i.e. Vos) applied to the gate of the respective switch. Failure may be identified by applying a control signal at a single voltage, or swept over a range of voltages, and comparing the actual voltage(s) (i.e. V_{DS}) associated with the control voltage(s) Ves, with the expected value(s) of Vos for the same value(s) of V_{GS}, based for example on a calibration curve of V_{DS} vs V_{GS} for the switch (which may be derived via experimentation or provided by the switch manufacturer). The electrical measurement unit 413 may optionally comprise a temperature sensor, power-supply voltage sensor, and switch current (I_{D}) sensor to allow the calibration curve to be corrected/selected to take into account the ambient temperature, supply voltage, and switch current. Taking into account the ranges of drain-to-source voltage (i.e. V_{DS}) associated with each of the cutoff, linear, and saturation modes of the switch as manufactured; a closed-circuit failure may be determined to have occurred if Vos is in a range associated with either of linear or saturation mode operation when the control voltage (i.e. V_{GS}) is in a range associated with cutoff mode operation, or if Vos is in a range associated with saturation mode operation when V_{GS} is in a range associated with linear or cutoff mode operation; and a open-circuit failure may be determined to have occurred if Vos is in a range associated with either of cutoff or linear mode operation when Vos is in a range associated with saturation mode operation; or if Vos is in a range associated with cutoff mode operation when Vos is in a range associated with linear or saturation mode operation, or if Vos is in a range associated with cutoff or linear mode operation when Vos is in a range associated with saturation mode operation. In other words, if the drain-to-source voltage (i.e. V_{DS}) across a given switch is lower than expected based on the normal value(s) for a given control voltage (i.e. Vos), the electrical measurement unit 413 may determine the switch is in an open-circuit failure, or if Vos across a given switch is greater than expected based on the normal value for Ves, the electrical measurement unit 413 may determine the switch is in an closed-circuit failure. More generally, a switch failure may be determined to have occurred if V_{DS} does not respond in the typical manner to a change in Ves.

Though not shown in FIG. 6, the controller package 400 may comprise switchable electrical lines enabling each of switches 421 and 422 to be independently connected to the supply voltage and the load (or to ground). Thus in the context of FIG. 6, if a first switch 421 has undergone complete open-circuit failure, such that no supply voltage can be supplied via the first switch 421 to the second switch 422, the supply voltage may be switched directly to node N2 to bypass the failed first switch 421, allowing the electrical parameters associated with the gate between drain and source of the second switch 422 to be measured as described above. Similarly, if a second switch 422 has undergone complete open-circuit failure, such that no connection from the source terminal of a first switch 421 can be made to the load/ground via the second switch 422, the load/ground may be switched directly to node N2 to bypass the failed second switch 422, allowing the electrical parameters associated with the gate between drain and source of the first switch 421 to be measured as described above

According to the approaches described above, if a first switch of the plurality of switches (e.g. one of switches 421 and 422 in the two-switch embodiment shown in FIG. 6) is determined to have failed, the control logic 410 may be configured to modify the provision of electrical current to the load terminal by switching at least one second switch of the plurality of switches to an open-circuit state based on determining the at least one first switch has failed, (e.g. via provision of an appropriate control voltage V_{GS} to the second switch, which will typically comprise the removal of the control voltage from the gate of the second switch). In response to detecting failure of one or more first switches, one or more second switches, which in some instances comprises all other switches of a plurality of switches on the current path between the power supply and load terminals, may be triggered to their open-circuit state (e.g. by removing gate voltages), and the power control unit 400 may be configured to maintain this condition regardless of whether signals are received at the power control unit 400/control logic 410 which would usually trigger the FET control unit 412 to close one or more switches.

When at least one switch is determined to be in an adverse operating condition, for example a failure state, the controller 400 may be configured in some embodiments to provide an alert signal. For example, the controller 400 may comprise a visual, audio, or haptic feedback unit, which is triggered to provide an alert to a user to indicate switch failure, or may be configured to provide signals (e.g. via one or more output pins) to an external computing device or feedback unit. The alert may generally indicate a switch failure has been detected, and may optionally more specifically indicate which of the switches has failed, and optionally whether the failure is complete, complete open failure, complete closed failure, or partial failure, to provide diagnostic information to a user.

The electrical measurement unit 413 of the power control unit 410 may be triggered to carry out monitoring/checks of whether each of the plurality of the switches is in an adverse operating state (e.g. a failure state) according to one of a number of approaches, which are applicable to all embodiments described herein. For example the control logic 410 may trigger checking of each switch on a periodic schedule, or may trigger checking of each switch as part of normal power control operation (e.g. as an initial step after signal has been received by the FET control unit 412 indicating one or more switch states should be changed), or the control logic 410 may trigger the electrical measurement unit 413 to carry out checking of the plurality of switches if one or more operational parameters associated with the power control unit 400 are determined to have changed beyond a predefined tolerance. For example, the electrical measurement unit 413 may monitor current (i.e. I_{D}) through the switched circuit path, and determine if the response of the current (e.g. in peak amplitude and/or rate of change) is different to the expected response given the battery charge state, the characteristics of the load, and the switching pattern applied by the FET control unit 412. An abnormal response may be determined if, for example, current continues to pass after one or more switches have been triggered to turn off, or current fails to rise to the expected level after all the switches have been turned on, or if the rate of rise or fall of current when switches are respectively closed and opened is more than a predefined threshold amount faster or slower than the expected value, as defined for example by testing when the controller 400 is first manufactured.

The inventor has recognised that whilst mitigating failure of one or more first switches via switching the state of one or more second switches in a power control unit 400 to an open-circuit state, and optionally providing a failure alert, may provide enhanced device safety, it may be desirable to incorporate functionality to the power supply unit 400 which enables early detection of adverse switch operating conditions, before complete failure occurs. Thus in some embodiments, the control logic 410 is configured to determine at least one first switch of the plurality of switches is in an adverse operating state by determining, prior to failure (e.g. complete failure) of the at least one first switch, that the at least one first switch is in a degraded operational condition (as defined further herein).

Accordingly, in these embodiments, the control logic 410 is configured to receive signals from at least one first switch status sensor configured to detect a first parameter associated with operation of at least one first switch 421, 422, wherein the control logic 410 is further configured to determine an indication of an operational condition of the at least one first switch on the basis of the received signals, and to determine whether at least one first switch of the plurality of switches is in an adverse operating state on the basis of the indication of operational condition. In approaches according to these embodiments, the control logic 410 is configured to receive signals from one or more switch status sensors, wherein each switch status sensor is configured and positioned relative to a respective first switch such that the signals output by the switch status sensor are indicative of at least one operating parameter of the at least one first switch. For example, in embodiments described further herein, a switch status sensor may be configured to output signals which are indicative of one or more electrical and/or environmental (e.g. temperature) parameters associated with the functioning of a given first switch of the plurality of switches (in that characteristics of the output signals change as switch functioning changes). According to one or more approaches described herein, the signals output by the switch status sensor are received by the control logic 410, which is configured to determine whether a first switch associated with the switch status sensor is in an adverse operating state (e.g. in a degraded operational condition). Typically, this determination is based on comparing, at the control logic 410, one or more parameters derived from output signals from one or more switch status sensors associated with a first switch comprised in the power control unit 400 with the value/value of said parameter(s) associated with one or more reference switches of the same type and of known operating condition/state. The ‘reference’ switch may comprise the same switch in its as-manufactured/pristine/virgin condition, and the reference value(s) may be derived for the switch by the control logic 410 of the power control unit 400 as part of initialisation of the power control unit 400 when it is first commissioned. As described further herein, the parameters derived from the output signal may be directly representative of physical parameters such as current, voltage, power, frequency, capacitance, resistance, conductance, inductance, or impedance, associated with electrical path elements of the respective switch (such as electrical path elements between the main terminals of the switch, and/or sub-paths within the switch), or, for example, the temperature(s) during operation of one or more elements of the switch, such as the gate or the die/chip/wafer in a FET context. Alternatively, the control logic 410 may be configured to derive one or more secondary parameters from one or more of these direct physical parameters, for example using an appropriate equation or algorithm (for example via a frequency-domain transform of a time-varying signal output from a switch status sensor). It will be appreciated that principles of measurement of electrical parameters as described herein may be carried out using measurement circuitry known to the skilled person (i.e. where measurements of electrical parameters are described herein, the electrical measurement unit 413 can be configured with functionality to carry out these measurements using approaches known to the skilled person, for example, using appropriate configurations of standard cells where the power control unit 400 comprises an ASIC package implementing control logic 410).

Typically, one or more switch status sensor(s) may be individually associated with respective ones of the at least one first switch, at least in that the measurements made by the sensor(s) enable operating parameters of each of the at least one first switch to be independently derived. In other words, the control logic 410 may be configured to determine a separate indication of the operational condition for each respective one of the at least one first switch. In other instances, respective ones of the at least one first switch status sensors may be individually associated with more than one of the at plurality of first switches, such that the measurements made by a single switch status sensor are influenced by the operating condition of more than one of the plurality of switches. In either scenario, the control logic 410 is configured to separately determine an adverse operating state for each respective one of the at least one first switch.

According to a first set of embodiments, the at least one switch status sensor is configured to measure/detect at least one electrical parameter associated with the operating state of the at least one first switch. In these embodiments, the switch status sensor for a given first switch typically comprises the electrical measurement unit 413 and associated electrical connections, and as such, may act as a switch status sensor configured to independently measure electrical parameters for each of a plurality of first switches. In one embodiment, the drain-to-source voltage (i.e. V_{DS}) for a given first switch at a given control voltage (i.e. Vs) may be used to as the indicator of operating condition used by the control logic 410 to determine the degree of degradation of said switch, as described in [1]. Alternatively, or in addition, the maximum peak amplitude of the drain to source current (i.e. I_{D}) ringing at the turn-off transient (i.e. when the control voltage (i.e. Ves) is removed from the gate of a given switch by the FET control unit 412) may be used to as the indicator of operating condition used by the control logic 410 to determine the degree of degradation of said switch, as described in [2]. Alternatively, or in addition, the control logic 410 may be configured to determine the presence of an adverse operating state associated with one or more first switches by analysing the frequency response of the drain to source voltage (i.e. Ves) as the gate current (I_{D}) is driven by the FET control unit 412 at a certain, predefined reference frequency. For example, a square wave control signal may be applied to the gate (G) of a given switch at a voltage amplitude which is associated with either linear or saturated operating regimes, and the frequency components of V_{GS} may be analysed to determine an indicator of operating condition, and thus a degree of degradation, based on the amplitudes of different frequency components (e.g. the first to third order components). In one implementation, the power control unit may be configured to determine a degree of degradation of at least one first switch using the Volterra series transform for the output signal of the switch, as described in [3]. Experimentation using reference switches of the same model as the switches used in the power control unit, having known degrees of degradation (e.g. expressed as a percentage of cycles to failure), may be used to parameterise a model used by the control logic 410 to quantify the degree of degradation as described in [3]. The degree of degradation may be expressed as a percentage of cycles to failure.

Alternatively, or in addition to the use of electrical parameters to determine operating condition of a given first switch, in some embodiments the switch status sensor may comprise a temperature sensor, and the temperature characteristics of the switch, part of the switch, and/or a region of the power control unit 400 in the vicinity of the switch, may be used to determine a degree of degradation. Without wishing to be bound by any particular theory, it is thought that some FET degradation modes are associated with detachment of the gate from the die, causing a degraded FET to exhibit different heat transfer characteristics between the gate and the die when compared to a pristine/virgin/as-manufactured FET. Because heat conduction away from the gate is typically impaired when the gate is partially detached from the die, higher gate operating temperatures are typically associated with the gate of a degraded FET, given fixed power dissipation and ambient temperature values. Thus, in some embodiments, the peak gate temperature and/or rate of change of gate temperature at a reference power dissipation value may be used to determine the degree of degradation of the FET, for example, according to the approach set out in [4]. FIG. 6 shows optional temperature sensors 431 and 432, respectively associated with switches 421 and 422, the temperature sensors being connected to a temperature control unit 411 (though the functions of the temperature control unit 411 could also be integrated into the electrical measurement unit 413). Where a temperature sensor is associated with a given first switch, this may typically be integrated into or attached to the gate to directly measure gate temperature (as in [4]), but may also be positioned on the die proximate to the gate (to infer the degree of heat transfer to the die from the gate). Temperature measurements derived using a switch status sensor may be calibrated/normalised by the temperature measurement unit 413 using a reference ambient temperature sensor measured at a position on the die away from the switch, or external to the power control unit 400 (and connected to it, for example, using one or more input terminals), or using one or more temperature values measured by the switch sensor at a time when the switch is not passing current.

In embodiments of the present disclosure, the control logic 411 may be configured to modify the provision of electrical current to the load terminal by switching at least one second switch of the plurality of switches to an open-circuit state based on determining the at least one first switch is in a degraded operational condition. In some instances, this may comprise switching one or more second switches to an open state (as described above in relation to detection of switch failure), or may comprise continuing to allow switching of the plurality of switches to a closed state to pass current to the load, under modified operating conditions. For example, in embodiments where the control logic 410 is configured to determine one or more first switches is in a degraded operational condition, without complete open- or closed-circuit failure having occurred, the control logic 410 may further quantify the degree of degradation, and modify one or more aspects of operation of the power control unit 400 on this basis. For example, the estimated degree of degradation of a given first switch may be quantified as a percentage of cycles to failure, which the control logic 410 is configured to determine, based on values derived for switches which have been cycled to failure whilst measuring the same switch operating parameter(s). For example, a calibration curve of a given operating parameter (e.g. gate temperature, rate of change of gate temperature, amplitude of different frequency components of Ves, drain to source voltage, or peak amplitude of the drain to source current (I_{D}) ringing at the turn-off transient), derived from pristine condition to complete failure for one or more samples for the same switch type, under the same or similar supply voltage conditions and ambient temperature in which the power supply unit 400 is to be used, may be used to estimate a percentage of elapsed lifetime (expressed, for example, in cycles, or watt-hours) until failure for a given first one of the plurality of switches. When the lifetime exceeds a certain threshold (for example, more than 50%, more than 60%, more than 70%, more than 80%, more than 90%, or more than 95%), the control logic 410 may modify operation of the power control unit 400 by, for example, reducing the operating power, reducing the switching frequency, or reducing the value of a safety cutoff temperature at which the control logic 410 sets at least one switch to an open-circuit condition to switch off the supply of power to the load.

Thus, according to embodiments of the present disclosure, the power control unit 400 (e.g. a power control ASIC package 400) may be configured to estimate a remaining lifetime of at least one first switches, based on the indication of the operational condition of the at least one first switch. In some embodiments, the estimated lifetime may comprise an estimated lifetime until the at least one first switch is in a degraded operational condition. In some embodiments, the estimated remaining lifetime may comprise an estimated lifetime until the at least one first switch fails (e.g. enters a complete failure state, as described further herein). In some embodiments, the estimated remaining lifetime may be expressed as a number of opening and closing cycles of the one or more first switches until failure or entry into a degraded operational condition is estimated to occur. In some embodiments, the estimated remaining lifetime may be expressed as a duration of current flow (e.g. expressed in units of power per unit time, such as watt-hours) through the one or more first switches. In some embodiments, the estimated remaining lifetime may be expressed as an amount of energy transmitted through the one or more first switches. As set out above, the parameterisation of remaining lifetime is typically achieved using data gathered via experiments conducted on switches of the same type as the switch whose remaining lifetime is to be estimated by the control logic 410. Test switches may be characterised using instrumentation corresponding to the switch state sensors and temperature and/or electrical measurement units described herein, with the test switches being cycled to failure under different loading conditions (e.g. supply voltage, peak power output, ambient temperature, and switching speed/duty cycle), which are representative of the use context in which the power control unit 400 is to be used. As each test switch is cycled to failure, at least one calibration curve is then derived plotting a certain ‘lifetime’ parameter (e.g. number of on/off cycles, power per unit time, duration of current flow, expressed for example in watts multiplied by time) over the lifetime to failure of the switch. During this experimentation, analysis of measured electrical/environmental parameters may be used to determine at what percentage of the elapsed lifetime the switch typically enters a degraded operating condition (as determined, for example, by detection of abnormal operating temperature, abnormal current flow, abnormal drain to source voltage, or abnormal on/off response time), and/or at what percentage of elapsed lifetime the switch typically enters a complete failure (e.g. open or closed failure) state. Thus, in use of the power control unit 400, the control logic 410 may use stored calibration information (e.g. in the form of one or more look-up tables), or one or more models or equations derived from it, to determine an estimated remaining lifetime based on one or more determined operating parameters/indications of operating condition during use of the power control unit 400.

Thus, in embodiments of the present disclosure, the control logic 410 may be configured to modify the provision of electrical current to the load terminal by switching at least one second switch of the plurality of switches to an open-circuit state based on determining a previously estimated remaining lifetime of at least one first switch has elapsed. At a given point in time, a remaining lifetime may be determined, which is set to be less than the estimated remaining lifetime until the first switch enters a degraded operational state, or undergoes complete failure. Switching at least one second switch to an open circuit condition when this estimated remaining lifetime has elapsed may provide enhanced safety, by deactivating the power control unit 400 before an adverse operating condition of any switch is reached. In any of the embodiments described herein, the power control unit 400 may be configured to modify the aspect of the provision of electrical current to the load terminal by reducing the electrical power of a supply of electrical current transmitted to the load terminal, based on determining a previously estimated remaining lifetime of at least one first switch has elapsed.

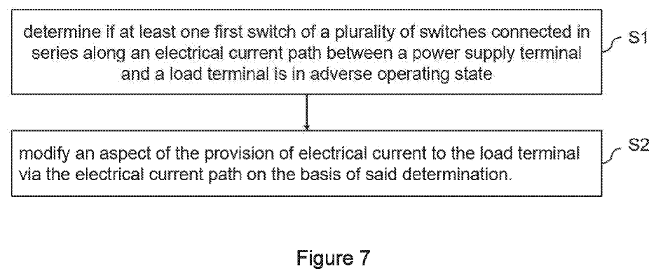

Thus there has been described a power control unit for controlling a supply of power on an electrical current path configured to connect at least one power supply terminal for connection to an electrical power supply to at least one load terminal for connection to an electrical load, via a plurality of switches connected in series along the electrical current path. With reference to FIG. 7, a method is also provided of operating such a power control unit to control a supply of power on an electrical current path configured to connect at least one power supply terminal for connection to an electrical power supply to at least one load terminal for connection to an electrical load, via a plurality of switches connected in series along the electrical current path; wherein the method comprises operating control logic comprised in the power control unit, the control logic being configured to supply electrical current to the load terminal via the electrical current path, to cause the control logic to independently switch each of the plurality of switches between an open-circuit state and a closed-circuit state; wherein the method comprises, in a first step, S1, determining if at least one first switch of the plurality of switches connected in series along an electrical current path between a power supply terminal and a load terminal is in adverse operating state; and, in a second step, S2, modifying an aspect of the provision of electrical current to the load terminal via the electrical current path on the basis of said determination. Both of steps S1 and S2 may be carried out in accordance with approaches described herein.

FIG. 8 will be recognised from FIG. 2 herein, and shows schematically an ASIC package 400 according to embodiments of the present disclosure. The ASIC package comprises control logic 410, configured to support a plurality of functions associated with an electronic device (e.g. an aerosol provision system) in which the ASIC package 400 is implemented. Aspects of the ASIC package as described in relation to FIG. 2 herein apply to an ASIC package 400 as schematically shown in FIG. 8, including, for example, design and fabrication (including design and fabrication of control logic), arrangement and functioning of terminals and interconnects, and positioning of hardware control logic on the die/chip/wafer. The ASIC package 400 may be provided as a configurable ASIC package, according to approaches set out herein for setting functional units of an ASIC package into one of a plurality of operating states, or may be provided as a non-configurable ASIC package in which the operating states of the functional units are not able to be set into one of a plurality of operating states according to approaches set out herein. FIG. 8 schematically shows an example of an ASIC package 400, comprising control logic 410 implementing a plurality of functional units 411 to 450 according to approaches set out further herein. In the example of FIG. 8, the control logic 410 comprises a plurality of safety-related functional units 411 to 420. Any of the safety-related functional units described herein may be implemented as one of the safety-related functional units 411 to 420. The control logic 410 may further comprise other functional units described herein, whether or not these are associated primarily with the provision of safety functionality. The control logic 410 comprises at least one dual-SW functional unit as described herein, each of which is configured to be triggered to set an open-circuit condition in response to a trigger signal directly or indirectly received from one or more of the safety-related functional units, according to approaches set out herein. In the example of FIG. 8, three dual-SW functional units are shown, though any number may be included in an ASIC package as set out further herein.

A first dual-SW functional unit 431 is connected to the V_{supply} terminal of the ASIC package configured to receive current from a battery, between the V_{supply} terminal and all other circuitry of the ASIC package configured to receive current from the battery, such that battery current can only pass to other circuitry of the ASIC package having passed through the dual-SW functional unit (via the plurality of solid-state switches).

A second dual-SW functional unit 432 is connected to a terminal of the ASIC package configured to receive current from a charging device (where the ASIC package is configured for use in a rechargeable host device), this terminal being P1 in the example of FIG. 8. The dual-SW functional unit is positioned between P1 and all other circuitry of the ASIC package configured to receive current from the charging device, such that battery current can only pass to other circuitry of the ASIC package having passed through the dual-SW functional unit (via the plurality of solid-state switches).

A third dual-SW functional unit 433 is connected to a terminal of the ASIC package configured to provide current from a power source to an external load in the host device, such as a heater in an aerosol delivery device context, this terminal being P8 in the example of FIG. 8. The dual-SW functional unit is positioned between any load powering circuitry of the ASIC package (e.g. a PC functional unit) and the terminal P8, such that current can only pass to the load having passed through the dual-SW functional unit (via the plurality of solid-state switches).

As described in the ‘dual switch (dual-SW) functional unit’ section herein, this can provide enhanced safety by enabling the isolation of the ASIC package from power sources (e.g. a charger and/or a battery) and/or a load (e.g. a heater) if a fault is determined by a safety-related functional unit of the ASIC package. The dual-SW configurations described in respect of FIG. 8 are exemplary, and as set out further herein, a larger or smaller number of dual-SW functional units (including no dual-SW functional units) may be provided, and these may be integrated into other functional units of the ASIC package.

In the example of FIG. 8, an airflow sensor 450 is further integrated into the ASIC package 400, though it will be appreciated this is optional as set out herein.

The various embodiments described herein are presented only to assist in understanding and teaching the claimed features. These embodiments are provided as a representative sample of embodiments only, and are not exhaustive and/or exclusive. It is to be understood that advantages, embodiments, examples, functions, features, structures, and/or other aspects described herein are not to be considered limitations on the scope of the invention as defined by the claims or limitations on equivalents to the claims, and that other embodiments may be utilised and modifications may be made without departing from the scope of the claimed invention. Various embodiments of the invention may suitably comprise, consist of, or consist essentially of, appropriate combinations of the disclosed elements, components, features, parts, steps, means, etc, other than those specifically described herein. In addition, this disclosure may include other inventions not presently claimed, but which may be claimed in future. The provision system described herein can be implemented as a combustible aerosol provision system, a non-combustible aerosol provision system or an aerosol-free delivery system.

Respective features of the present disclosure are defined by the following numbered paragraphs:
Paragraph 1. A power control unit, comprising:
   at least one power supply terminal for connection to an electrical power supply;
   at least one load terminal for connection to an electrical load;
   an electrical current path configured to connect the at least one power supply terminal to the at least one load terminal; and
   a plurality of switches connected in series along the electrical current path, wherein the power control unit comprises control logic configured to independently switch each of the plurality of switches between an open-circuit state and a closed-circuit state;
   wherein the control logic is configured to supply electrical current to the load terminal via the electrical current path; and
   wherein the control logic is further configured to determine if at least a first switch of the plurality of switches is in an adverse operating state, and to modify an aspect of the provision of electrical current to the load terminal via the electrical current path on the basis of said determination.
Paragraph 2. The power control unit of paragraph 1, wherein the determination at least one first switch of the plurality of switches is in an adverse operating state comprises a determination the at least one first switch has failed.
Paragraph 3. The power control unit of paragraph 2, wherein the determination at least one first switch of the plurality of switches is in an adverse operating state comprises a determination the at least one first switch has failed non-reversibly in a closed-circuit state.
Paragraph 4. The power control unit of paragraph 1, wherein the determination at least one first switch of the plurality of switches is in an adverse operating state comprises a determination, prior to failure of the at least one first switch, that the at least one first switch has entered a degraded operational condition.
Paragraph 5. The power control unit of any of paragraphs 2 to 3, wherein the modification of the aspect of the provision of electrical current to the load terminal comprises switching at least one second switch of the plurality of switches to an open-circuit state based on determining the at least one first switch has failed.
Paragraph 6. The power control unit of paragraph 4, wherein the modification of the aspect of the provision of electrical current to the load terminal comprises switching at least one second switch of the plurality of switches to an open-circuit state based on determining the at least one first switch has entered a degraded operational condition.
Paragraph 7. The power control unit of paragraph 4, wherein the modification of the aspect of the provision of electrical current to the load terminal comprises reducing the electrical power of a supply of electrical current transmitted to the load terminal.
Paragraph 8. The power control unit of any of paragraphs 1 to 7, further operable to receive signals from at least one first switch status sensor configured to detect a first parameter associated with operation of at least one first switch, wherein the power control unit is configured to determine an indication of an operational condition of the at least one first switch on the basis of the received signals, and to determine whether the at least one first switch of the plurality of switches is in an adverse operating state on the basis of the indication of operational condition.
Paragraph 9. The power control unit of paragraph 8, wherein the first parameter comprises an operating temperature of the at least one first switch, and the received signals are representative of the operating temperature.
Paragraph 10. The power control unit of any of paragraphs 8 and 9, wherein the first parameter comprises an electrical resistance of the at least one first switch, and the received signals are representative of the electrical resistance.
Paragraph 11. The power control unit of any of paragraphs 8 to 10, wherein the first parameter comprises a response time of the at least one first switch to a control signal applied to change the switch state, and the received signals are representative of the response time.
Paragraph 12. The power control unit of any of paragraphs 8 to 11, wherein the power control unit is configured to estimate a remaining lifetime of the at least one first switch, based on the indication of the operational condition of the at least one first switch.
Paragraph 13. The power control unit of paragraph 12, wherein the estimated lifetime comprises an estimated lifetime until the at least one first switch is in a degraded operational condition.
Paragraph 14. The power control unit of any of paragraphs 12 to 13, wherein the estimated lifetime comprises an estimated lifetime until the at least one first switch fails.
Paragraph 15. The power control unit of any of paragraphs 12 to 14, wherein the estimated remaining lifetime is expressed as a number of opening and closing cycles of the at least one first switch.
Paragraph 16. The power control unit of any of paragraphs 12 to 15, wherein the estimated remaining lifetime is expressed as a duration of current flow through the at least one first switch.
Paragraph 17. The power control unit of any of paragraphs 12 to 16, wherein the estimated remaining lifetime is expressed as an amount of energy transmitted through the at least one first switch.
Paragraph 18. The power control unit of any of paragraphs 12 to 17, wherein the modification of the aspect of the provision of electrical current to the load terminal comprises switching at least one second switch of the plurality of switches to an open-circuit state based on determining a previously estimated remaining lifetime of at least one first switch has elapsed.
Paragraph 19. The power control unit of any of paragraphs 8 to 18, wherein respective ones of the at least one first switch status sensors are individually associated with respective ones of the at least one first switch.
Paragraph 20. The power control unit of any of paragraphs 8 to 18, wherein the at least one first switch comprises a plurality of first switches, and wherein respective ones of the at least one first switch status sensors are individually associated with more than one of the plurality of first switches.
Paragraph 21. The power control unit of any of paragraphs 8 to 20, wherein the at least one first switch comprises a plurality of first switches, and wherein the power control unit is configured to determine a separate indication of the operational condition for each respective one of the plurality of first switches.
Paragraph 22. The power control unit of any of paragraphs 1 to 21, wherein the at least one first switch comprises a plurality of first switches, and wherein the power control unit is configured to separately determine an adverse operating state for each respective one of the plurality of first switches.
Paragraph 23. The power control unit of any of paragraphs 1 to 22, wherein the plurality of switches comprises two switches.
Paragraph 24. The power control unit of any of paragraphs 1 to 23, wherein the plurality of switches comprise solid state switches.
Paragraph 25. The power control unit of paragraph 24, wherein the plurality of switches comprise field effect transistor, FET, switches.
Paragraph 26. The power control unit of any of paragraphs 1 to 25, wherein the power control unit comprises an application specific integrated circuit, ASIC, package.
Paragraph 27. The power control unit of any of paragraphs 1 to 26, comprising control logic configured to detect a trigger signal provided by an actuation element, and to control the supply of electrical current to the load terminal via the electrical current path on the basis of the trigger signal.
Paragraph 28. The power control unit of paragraph 27, wherein the actuation element comprises a MEMS airflow sensor.
Paragraph 29. The power control unit of paragraph 28 when dependent on paragraph 26, wherein the actuation element is integrated into an ASIC package.
Paragraph 30. The power control unit of paragraph 29, wherein the ASIC package comprises a single, semiconductor die.
Paragraph 31. An aerosol provision device comprising an electrical power supply, an electrical load comprising an aerosol generator, and the power control unit of any preceding paragraph, wherein the at least one power supply terminal is electrically connected to the electrical power supply, and the at least one load terminal is electrically connected to the electrical load.
Paragraph 32. An aerosol provision system comprising the aerosol provision device of paragraph 31.
Paragraph 33. A method of operating a power control unit to control a supply of power on an electrical current path configured to connect at least one power supply terminal for connection to an electrical power supply to at least one load terminal for connection to an electrical load, via a plurality of switches connected in series along the electrical current path; wherein the method comprises operating control logic comprised in the power control unit, the control logic being configured to supply electrical current to the load terminal via the electrical current path, to cause the control logic to independently switch each of the plurality of switches between an open-circuit state and a closed-circuit state; wherein the method comprises, at the control logic:
   determining if at least a first switch of the plurality of switches is in an adverse operating state, and
   modifying an aspect of the provision of electrical current to the load terminal via the electrical current path on the basis of said determination.
Paragraph 34. A computer program product comprising instructions to cause the power control unit of paragraph 1 to execute the steps of the method of paragraph 33.
Paragraph 35. A computer-readable medium having stored thereon the computer program of paragraph 34.
Paragraph 36. An application specific integrated circuit, ASIC, package, for use in an electrical or electronic device, the ASIC package comprising:
   a plurality of functional units, wherein each of the plurality of functional units is configured with control logic operable to provide a discrete monitoring and/or control function associated with an aspect of operation of the electrical or electronic device, and wherein an operating status of each of the functional units is independently configurable into one of an enabled and non-enabled operational state; and
   a plurality of terminals, comprising a plurality of input and/or output terminals, wherein each one of the plurality of input and/or output terminals is connected to at least one of the plurality of functional units;
   wherein the ASIC package is configured to be set into a target functional configuration selected from a plurality of different functional configurations, wherein each of the plurality of functional configurations comprises a different combination of operating states associated with respective ones of the plurality of functional units.
Paragraph 37. The ASIC package of paragraph 36, configured to be set into the target functional configuration in a reversible manner.
Paragraph 38. The ASIC package of paragraph 37, further comprising one or more diodes, wherein the ASIC package is configured to be set into the target functional configuration by setting a state of at least one of the one or more diodes.
Paragraph 39. The ASIC package of paragraph 36, configured to be set into the target functional configuration in a non-reversible manner.
Paragraph 40. The ASIC package of paragraph 39, configured to be set into the target functional configuration via physical manipulation of at least one structural element of the ASIC package.
Paragraph 41. The ASIC package of paragraph 40, wherein the structural element comprises one or more fusible links, and the physical manipulation comprises breaking of the at least one fusible link.
Paragraph 42. The ASIC package of paragraph 41, further comprising control logic configured to cause a current to be applied through the at least one fusible link suitable to cause the breaking of the fusible link.
Paragraph 43. The ASIC package of paragraph 40, wherein the physical manipulation of the at least one structural element comprises removing conductive material from a portion of the ASIC package to break an existing current path between a predefined pair of electrical nodes.
Paragraph 44. The ASIC package of paragraph 43, wherein the conductive material is configured to be removed via a mechanical process, a chemical process, or a laser ablation process.
Paragraph 45. The ASIC package of paragraph 40, wherein the physical manipulation of the at least one structural element comprises forming a new current path between a predefined pair of electrical nodes.
Paragraph 46. The ASIC package of paragraph 44, wherein each predefined pair of electrical nodes is configured to be connected to form a new current path by addition of conductive material via soldering.
Paragraph 47. The ASIC package of paragraph 37, further comprising a memory element, and further comprising control logic configured to store a value in the memory element, the value being one of a set of predefined values respectively associated with the plurality of functional configurations, wherein the control logic is further operable to set as the functional configuration a one of the plurality of different functional configurations which is associated with the one of the predefined values.
Paragraph 48. The ASIC package of any of paragraphs 37 to 42, or 47, configured to set the selected functional configuration based on detection of at least one predefined characteristic of an input signal applied to one or more of the plurality of terminals, wherein a potential functional configuration to be set by the ASIC package is associated with each predefined characteristic.
Paragraph 49. The ASIC package of paragraph 48, wherein the predefined characteristic comprises a combination of one or more of the plurality of terminals at which the input signal is detected, and wherein the ASIC package is configured with control logic operable to set as the functional configuration a one of the plurality of different functional configurations which is associated with a specific combination of the one or more of the plurality of terminals at which the input signal is detected.
Paragraph 50. The ASIC package of any of paragraphs 48 to 49, wherein the predefined characteristic comprises a voltage detected at the one or more of the plurality of terminals, and wherein the ASIC package is configured with control logic operable to set as the functional configuration a one of the plurality of different functional configurations which is associated with a range of voltage associated with the voltage of the input signal.
Paragraph 51. The ASIC package of any of paragraphs 48 to 49, wherein the predefined characteristic comprises a signal pattern detected at one or more of the plurality of terminals, and wherein the ASIC package is configured with control logic operable to set as the functional configuration a one of the plurality of different functional configurations which is associated with a signal pattern of the input signal.
Paragraph 52. The ASIC package of paragraph 51, wherein the signal pattern comprises a frequency of the signal.
Paragraph 53. The ASIC package of any of paragraphs 48 to 52, wherein at least one of the one or more of the plurality of terminals comprises at least one control terminal not associated with the control, by the plurality of functional units, of any of the aspects of operation associated with the electrical or electronic device.
Paragraph 54. The ASIC package of paragraph 53, wherein the one or more of the plurality of terminals comprises the control terminal and a ground, GND, terminal.
Paragraph 55. The ASIC package of any of paragraphs 36 to 54, wherein each of the plurality of functional units is connected to a discrete subset of the plurality of input and/or output terminals.
Paragraph 56. The ASIC package of any of paragraphs 36 to 55, wherein each of the plurality of functional units is operable to monitor inputs to and/or provide outputs to a discrete subset of the plurality of input and/or output terminals.
Paragraph 57. The ASIC package of any of paragraphs 36 to 56, wherein the plurality of input and/or output terminals comprises a ground, GND, terminal and a positive supply line, VCC, terminal.
Paragraph 58. The ASIC package of any of paragraphs 36 to 57, further configured to be set into a selected functional configuration following manufacture via a semiconductor device fabrication process.
Paragraph 59. The ASIC package of any of paragraphs 36 to 58, further configured to be set into a selected functional configuration following assembly into an electrical or electronic device.
Paragraph 60. The ASIC package of any of paragraphs 36 to 59, wherein the plurality of functional units comprise physical modules of circuitry comprised in a single semiconductor die.
Paragraph 61. The ASIC package of any of paragraphs 36 to 60, wherein the electrical or electronic device comprises an aerosol provision system.
Paragraph 62. The ASIC package of paragraph 61, wherein the aspects of operation in association with which the plurality of functional units are configured to provide monitoring and/or control functions are aspects of operation of an aerosol provision system selected from a list comprising:
   control of current to an aerosol generator.
   control of one or more display elements.
   control of a haptic feedback element.
   monitoring of a user input interface.
   control of charging of a power supply comprised in the electronic aerosol provision system.
   monitoring of a temperature associated with a operation of the aerosol provision system
   monitoring of a temperature of a power source and/or power controller circuitry of the aerosol provision system.
   monitoring of any interruption or error state associated with operation of the ASIC package and/or the aerosol provision system.
Paragraph 63. The ASIC package of any paragraph of paragraphs 36 to 62 wherein at least one of the functional units is configured to provide a monitoring function comprising determining occurrence of a fault condition, and perform a control function comprising triggering of a safety-related function in response to a fault condition being determined.
Paragraph 64. The ASIC package of paragraph 63, wherein determining occurrence of a fault condition comprises one or more of:
   determining a presence of an over-voltage condition associated with charging of a power supply element external to the ASIC package.
   determining a presence of an over-current condition associated with charging of a power supply element external to the ASIC package.
   determining a presence of an over-voltage condition associated with discharge to a load from a power supply element external to the ASIC package.
   determining a presence of an over-current condition associated with discharge to a load of a power supply element external to the ASIC package.
   determining a presence of a short-circuit condition on a current path external to the ASIC package.
   determining a presence of an ultra-low-voltage condition associated with a power supply element external to the ASIC package.
   determining a discharge of power from a power supply element to a load external to the ASIC package has exceeded a threshold duration of time.
   determining a presence of an over-temperature condition associated with a power supply element external to the ASIC package.
   determining a presence of an under-temperature condition associated with a power supply element external to the ASIC package.
   determining a presence of an incorrect polarity of a charging current associated with charging of a power supply element external to the ASIC package.
Paragraph 65. The ASIC package of any of paragraphs 63 to 64, wherein triggering of the safety related function comprises triggering of an open-circuit condition for at least one switch on a current path associated with supply of charging current to a power supply element.
Paragraph 66. The ASIC package of any of paragraphs 63 to 65, wherein triggering of the safety related function comprises triggering of an open-circuit condition for at least one switch on a current path associated with discharge of current from a power supply element to a load.
Paragraph 67. The ASIC package of any of paragraphs 63 to 66, wherein triggering the safety related function comprises triggering of an open-circuit condition for at least one switch on a current path associated with supply of current from a power supply element to at least one functional unit of the ASIC package.
Paragraph 68. The ASIC package of any of paragraphs 65 to 67, wherein the at least one switch is integrated into a functional unit of the ASIC package.
Paragraph 69. The ASIC package of any of paragraphs 63 to 68, wherein triggering of the safety-related function comprises triggering the ASIC package to power down.
Paragraph 70. The ASIC package of any paragraph of paragraphs 36 to 69, wherein an operating status of at least one of the functional units is independently configurable into a plurality of enabled operating states.
Paragraph 71. The ASIC package of paragraph 70, wherein each of the plurality of enabled operating states of a given functional unit of the at least one functional units is associated with different predetermined operating data to be used by control logic of the given functional unit to provide a discrete monitoring and/or control function.
Paragraph 72. The ASIC package of paragraph 71, wherein the different predetermined operating data associated with each of the plurality of enabled operating states comprises different parameter values or sets of parameter values.
Paragraph 73. The ASIC package of paragraph 72, wherein the different parameter values or sets of parameter values comprise one or more matrices accessible by the functional unit.
Paragraph 74. The ASIC package of paragraph 71, wherein the different predetermined operating data associated with each of the plurality of enabled operating states comprises machine code.
Paragraph 75. The ASIC package of any of paragraphs 71 to 74, wherein the different predetermined operating data associated with each of the plurality of enabled operating states of the given functional unit is stored in a memory element of the ASIC package, and the given functional unit is configured into a target operating state of the plurality of enabled operating states by accessing from the memory element predetermined operating data associated with the enabled operating state.
Paragraph 76. The ASIC package of paragraph 75, wherein the memory element comprises a register.
Paragraph 77. The ASIC package of paragraph 76, wherein the memory element is integrated into the given functional unit.
Paragraph 78. The ASIC package of any paragraph of paragraphs 36 to 77, wherein the ASIC package comprises a switching functional unit, the switching functional unit comprising plurality of switches connected in series along an electrical current path within the ASIC package, wherein the switching functional unit further comprises switching control logic configured to independently switch each of the plurality of switches between an open-circuit state and a closed-circuit state; and wherein the switching functional unit is configured to open at least one of the plurality of switches to an open circuit state in response to receiving a trigger signal from one of the plurality of functional units of the ASIC package, the trigger signal indicating a fault condition has been determined by said one of the functional units.
Paragraph 79. The ASIC package of paragraph 78, wherein the switching control logic is configured to determine if at least a first switch of the plurality of switches is in an adverse operating state, and to modify an aspect of the provision of electrical current to the load terminal via the electrical current path on the basis of said determination.
Paragraph 80. An aerosol provision device comprising the ASIC package of any paragraph of paragraphs 36 to 79.
Paragraph 81. An aerosol provision system comprising the aerosol provision device of paragraph 80.
Paragraph 82. A method of modifying an application specific integrated circuit, ASIC, package, for use in an electrical or electronic device, the ASIC package comprising:
   a plurality of functional units, wherein each of the plurality of functional units is configured with control logic operable to provide a discrete monitoring and/or control function associated with an aspect of operation of the electrical or electronic device, and wherein an operating status of each of the functional units is independently configurable into one of an enabled and non-enabled operational state; and
   a plurality of terminals, comprising a plurality of input and/or output terminals, wherein each one of the plurality of input and/or output terminals is connected to at least one of the plurality of functional units;
   wherein the method comprises setting the ASIC package into a target functional configuration selected from a plurality of different functional configurations, wherein each of the plurality of functional configurations comprises a different combination of operating states associated with respective ones of the plurality of functional units.
Paragraph 83. A data processing apparatus comprising means for carrying out the method of paragraph 82.
Paragraph 84. A computer program product comprising instructions which, when the program is executed by a computer, cause the computer to carry out the method of paragraph 82.
Paragraph 85. A computer-readable medium having stored thereon the computer program product of paragraph 84.

### REFERENCES

[1] Patil N., Celaya J., Das D. Precursor parameter identification for insulated gatebipolar transistor (IGBT) prognostics. IEEE Trans. Reliab. 2009; 58:276-278
[2] Sonnenfeld G., Goebel K., Celaya J. R. An agile accelerated aging, characterization and scenario simulation system for gate controlled power transistors. IEEE Autotestcon. 2008; 6:208-215
[3] Wu L F, Zheng Y, Guan Y, Wang G H, Li X J., “A non-intrusive method for monitoring the degradation of MOSFETs”, Sensors (Basel). 2014 Jan. 10; 14(1): 1132-9
[4] Celaya, J R., et al. “Towards prognostics of power MOSFETs: Accelerated aging and precursors of failure”, National Aeronautics And Space Administration Moffett Field Ca Ames Research Center, 2010

1. An application specific integrated circuit, ASIC, package, for use in an electrical or electronic device, the ASIC package comprising:
a plurality of functional units, wherein each of the plurality of functional units is configured with control logic operable to provide a discrete monitoring and/or control function associated with an aspect of operation of the electrical or electronic device, and wherein an operating status of each of the functional units is independently configurable into one of an enabled and non-enabled operational state; and
a plurality of terminals, comprising a plurality of input and/or output terminals, wherein each one of the plurality of input and/or output terminals is connected to at least one of the plurality of functional units;
wherein the ASIC package is configured to be set into a target functional configuration selected from a plurality of different functional configurations, wherein each of the plurality of functional configurations comprises a different combination of operating states associated with respective ones of the plurality of functional units.

2. The ASIC package of claim 1, configured to be set into the target functional configuration in a reversible manner.

3. The ASIC package of claim 1, configured to be set into the target functional configuration in a non-reversible manner.

4. The ASIC package of claim 3, configured to be set into the target functional configuration via physical manipulation of at least one structural element of the ASIC package.

5. The ASIC package of claim 2, further comprising a memory element, and further comprising control logic configured to store a value in the memory element, the value being one of a set of predefined values respectively associated with the plurality of functional configurations, wherein the control logic is further operable to set as the functional configuration a one of the plurality of different functional configurations which is associated with the one of the predefined values.

6. The ASIC package of claim 2, configured to set the selected functional configuration based on detection of at least one predefined characteristic of an input signal applied to one or more of the plurality of terminals, wherein a potential functional configuration to be set by the ASIC package is associated with each predefined characteristic.

7. The ASIC package of claim 1, wherein the electrical or electronic device comprises an aerosol provision system.

8. The ASIC package of claim 7, wherein the aspects of operation in association with which the plurality of functional units are configured to provide monitoring and/or control functions are aspects of operation of an aerosol provision system selected from a list comprising:
control of current to an aerosol generator.
control of one or more display elements.
control of a haptic feedback element.
monitoring of a user input interface.
control of charging of a power supply comprised in the electronic aerosol provision system.
monitoring of a temperature associated with a operation of the aerosol provision system
monitoring of a temperature of a power source and/or power controller circuitry of the aerosol provision system.
monitoring of any interruption or error state associated with operation of the ASIC package and/or the aerosol provision system.

9. The ASIC package of claim 1, wherein at least one of the functional units is configured to provide a monitoring function comprising determining occurrence of a fault condition, and perform a control function comprising triggering of a safety-related function in response to a fault condition being determined.

10. The ASIC package of claim 9, wherein determining occurrence of a fault condition comprises one or more of:
determining a presence of an over-voltage condition associated with charging of a power supply element external to the ASIC package.
determining a presence of an over-current condition associated with charging of a power supply element external to the ASIC package.
determining a presence of an over-voltage condition associated with discharge to a load from a power supply element external to the ASIC package.
determining a presence of an over-current condition associated with discharge to a load of a power supply element external to the ASIC package.
determining a presence of a short-circuit condition on a current path external to the ASIC package.
determining a presence of an ultra-low-voltage condition associated with a power supply element external to the ASIC package.
determining a discharge of power from a power supply element to a load external to the ASIC package has exceeded a threshold duration of time.
determining a presence of an over-temperature condition associated with a power supply element external to the ASIC package.
determining a presence of an under-temperature condition associated with a power supply element external to the ASIC package.
determining a presence of an incorrect polarity of a charging current associated with charging of a power supply element external to the ASIC package.

11. The ASIC package of claim 9, wherein triggering of the safety related function comprises triggering of an open-circuit condition for at least one switch on a current path associated with supply of charging current to a power supply element.

12. The ASIC package of claim 9, wherein triggering of the safety related function comprises triggering of an open-circuit condition for at least one switch on a current path associated with discharge of current from a power supply element to a load.

13. The ASIC package of claim 9, wherein triggering the safety related function comprises triggering of an open-circuit condition for at least one switch on a current path associated with supply of current from a power supply element to at least one functional unit of the ASIC package.

14. The ASIC package of claim 9, wherein triggering of the safety-related function comprises triggering the ASIC package to power down.

15. The ASIC package of claim 1, wherein an operating status of at least one of the functional units is independently configurable into a plurality of enabled operating states.

16. The ASIC package of claim 15, wherein each of the plurality of enabled operating states of a given functional unit of the at least one functional units is associated with different predetermined operating data to be used by control logic of the given functional unit to provide a discrete monitoring and/or control function.

17. The ASIC package of claim 16, wherein the different predetermined operating data associated with each of the plurality of enabled operating states comprises different parameter values or sets of parameter values.

18. The ASIC package of claim 16, wherein the different predetermined operating data associated with each of the plurality of enabled operating states of the given functional unit is stored in a memory element of the ASIC package, and the given functional unit is configured into a target operating state of the plurality of enabled operating states by accessing from the memory element predetermined operating data associated with the enabled operating state.

19. The ASIC package of claim 18, wherein the memory element comprises a register.

20. The ASIC package of claim 1, wherein the ASIC package comprises a switching functional unit, the switching functional unit comprising plurality of switches connected in series along an electrical current path within the ASIC package, wherein the switching functional unit further comprises switching control logic configured to independently switch each of the plurality of switches between an open-circuit state and a closed-circuit state; and wherein the switching functional unit is configured to open at least one of the plurality of switches to an open circuit state in response to receiving a trigger signal from one of the plurality of functional units of the ASIC package, the trigger signal indicating a fault condition has been determined by said one of the functional units.

21. An aerosol provision device comprising the ASIC package of claim 1.

22. A method of modifying an application specific integrated circuit, ASIC, package, for use in an electrical or electronic device, the ASIC package comprising: a plurality of functional units, wherein each of the plurality of functional units is configured with control logic operable to provide a discrete monitoring and/or control function associated with an aspect of operation of the electrical or electronic device, and wherein an operating status of each of the functional units is independently configurable into one of an enabled and non-enabled operational state; and a plurality of terminals, comprising a plurality of input and/or output terminals, wherein each one of the plurality of input and/or output terminals is connected to at least one of the plurality of functional units;
wherein the method comprises setting the ASIC package into a target functional configuration selected from a plurality of different functional configurations, wherein each of the plurality of functional configurations comprises a different combination of operating states associated with respective ones of the plurality of functional units.

23. A data processing apparatus comprising means for carrying out the method of claim 22.

24. A computer program product comprising instructions which, when the program is executed by a computer, cause the computer to carry out the method of claim 22.

25. A computer-readable medium having stored thereon the computer program product of claim 24.
